(19) United States
(12) Patent Application Publication
(10) Pub. No.: US 2024/0136320 A1
(43) Pub. Date: Apr. 25, 2024

(54) SEMICONDUCTOR DEVICE

(71) Applicant: ROHM CO., LTD., Kyoto-shi (JP)

(72) Inventor: Kohei TANIKAWA, Kyoto-shi (JP)

(21) Appl. No.: 18/532,726

(22) Filed: Dec. 7, 2023

Related U.S. Application Data
(63) Continuation of application No. PCT/JP2022/027699, filed on Jul. 14, 2022.

(30) Foreign Application Priority Data
Aug. 9, 2021 (JP) 2021-130755

(51) Int. Cl. H01L 23/00; H01L 23/31; H01L 25/07

(52) U.S. Cl. CPC H01L 24/40; H01L 23/3121; H01L 24/37; H01L 25/072; H01L 23/49527; H01L 24/05; H01L 24/06; H01L 24/32; H01L 24/45; H01L 24/48; H01L 24/73; H01L 2224/05553; H01L 2224/05554; H01L 2224/05639; H01L 2224/0603; H01L 2224/06051; H01L 2224/06181; H01L 2224/32245; H01L 2224/37011; H01L 2224/37147; H01L 2224/40137; H01L 2224/40175; H01L 2224/45124; H01L 2224/45144; H01L 2224/45147; H01L 2224/48227; H01L 2224/73221; H01L 2224/73263; H01L 2224/73265

(57) ABSTRACT

A semiconductor device includes a conductive substrate including an obverse surface facing a first side in thickness direction and a reverse surface opposite from the obverse surface, a first switching semiconductor element bonded to the obverse surface, a first conductive member for passing main circuit current switched by the semiconductor element, and a sealing resin covering the semiconductor element, the conductive member and a part of the substrate. The substrate includes first and second conductive portions mutually spaced in first direction orthogonal to thickness direction. The semiconductor element is electrically bonded to the first conductive portion. The conductive member includes a first part overlapping with the first and the second conductive portions as viewed in thickness direction and being spaced from the obverse surface toward the first side in thickness direction. The first part includes a first opening.

### TECHNICAL FIELD

The present disclosure relates to a semiconductor device.

### BACKGROUND ART

Semiconductor devices with power switching elements, such as MOSFETs (Metal Oxide Semiconductor Field Effect Transistors) or IGBTs (Insulated Gate Bipolar Transistors), are conventionally known. These semiconductor devices are used in a variety of electronic equipment, including industrial equipment, home appliances, information terminals, and automotive equipment. A conventional semiconductor device (power module) is disclosed in JP-A-2015-220382. The semiconductor device disclosed in JP-A-2015-220382 includes a semiconductor element, a support substrate, and a sealing resin. The semiconductor element is, for example, an IGBT made of Si (silicon). The support substrate supports the semiconductor element. The support substrate includes an insulating base and conductive layers provided on an obverse surface and a reverse surface of the base. The base is made of a ceramic material, for example. The conductive layers are made of Cu (copper), for example, and the semiconductor element is bonded to one of the conductive layers. The semiconductor element is covered with the sealing resin.

### BRIEF DESCRIPTION OF THE DRAWINGS

FIG. 1 is a perspective view of a semiconductor device according to a first embodiment of the present disclosure.

FIG. 2 is a perspective view corresponding to FIG. 1, from which a sealing resin is omitted.

FIG. 3 is a perspective view corresponding to FIG. 2, from which a first conductive member is omitted.

FIG. 4 is a plan view of the semiconductor device shown in FIG. 1.

FIG. 5 is a plan view corresponding to FIG. 4, in which the sealing resin is indicated by imaginary lines.

FIG. 6 is a right side view of the semiconductor device shown in FIG. 1, in which the sealing resin is indicated by imaginary lines.

FIG. 7 is a partially enlarged view in which a portion of FIG. 5 is enlarged, with the sealing resin omitted.

FIG. 8 is a plan view of the second conductive member.

FIG. 9 is a plan view corresponding to FIG. 5, from which the sealing resin and the second conductive member are omitted.

FIG. 10 is a plan view corresponding to FIG. 9, in which the first conductive member is indicated by imaginary lines.

FIG. 11 is a right side view of the semiconductor device shown in FIG. 1.

FIG. 12 is a bottom view of the semiconductor device shown in FIG. 1.

FIG. 13 is a sectional view taken along line XIII-XIII in FIG. 5.

FIG. 14 is a sectional view taken along line XIV-XIV in FIG. 5.

FIG. 15 is a partially enlarged view in which a portion of FIG. 14 is enlarged.

FIG. 16 is a partially enlarged view in which a portion of FIG. 14 is enlarged.

FIG. 17 is a partially enlarged view in which a portion of FIG. 14 is enlarged.

FIG. 18 is a sectional view taken along line XVIII-XVIII in FIG. 5.

FIG. 19 is a sectional view taken along line XIX-XIX in FIG. 5.

FIG. 20 is a sectional view taken along line XX-XX in FIG. 5.

FIG. 21 is a plan view corresponding to FIG. 7 (with the sealing resin omitted), showing a semiconductor device according to a variation of the first embodiment.

FIG. 22 is a plan view of a semiconductor device according to a variation of the first embodiment, from which the sealing resin and the second conductive member are omitted.

FIG. 23 is a sectional view taken along line XXIII-XXIII in FIG. 21.

FIG. 24 is a partially enlarged view in which a portion of FIG. 23 is enlarged.

### DETAILED DESCRIPTION OF EMBODIMENTS

The following describes preferred embodiments of the present disclosure with reference to the drawings.

In the present disclosure, the terms such as “first”, “second”, and “third” are used merely as labels and are not intended to impose ordinal requirements on the items to which these terms refer.

In the description of the present disclosure, the expression “An object A is formed in an object B”, and “An object A is formed on an object B” imply the situation where, unless otherwise specifically noted, “the object A is formed directly in or on the object B”, and “the object A is formed in or on the object B, with something else interposed between the object A and the object B”. Likewise, the expression “An object A is arranged in an object B”, and “An object A is arranged on an object B” imply the situation where, unless otherwise specifically noted, “the object A is arranged directly in or on the object B”, and “the object A is arranged in or on the object B, with something else interposed between the object A and the object B”. Further, the expression “An object A is located on an object B” implies the situation where, unless otherwise specifically noted, “the object A is located on the object B, in contact with the object B”, and “the object A is located on the object B, with something else interposed between the object A and the object B”. Still further, the expression “An object A overlaps with an object B as viewed in a certain direction” implies the situation where, unless otherwise specifically noted, “the object A overlaps with the entirety of the object B”, and “the object A overlaps with a part of the object B”.

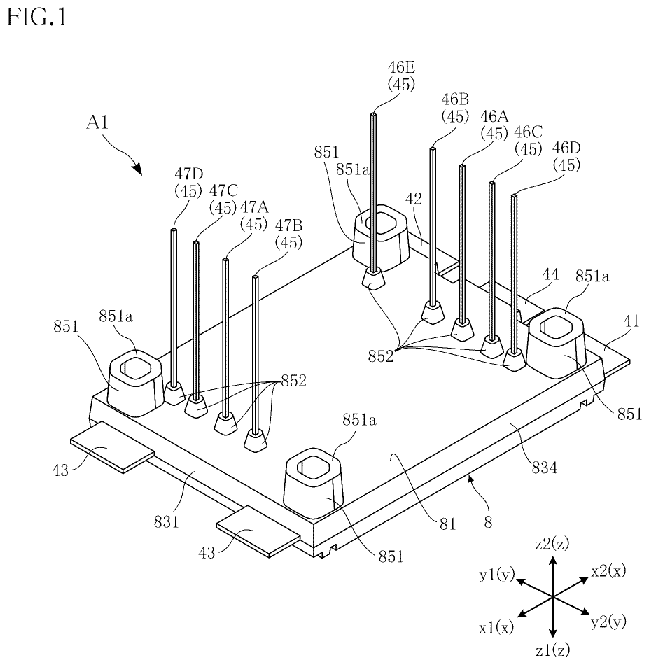

FIGS. 1 to 20 show a semiconductor device according to a first embodiment of the present disclosure. The semiconductor device A1 of the present embodiment includes a plurality of first semiconductor elements 10A, a plurality of second semiconductor elements 10B, a conductive substrate 2, a support substrate 3, a first terminal 41, a second terminal 42, a plurality of third terminals 43, a fourth terminal 44, a plurality of control terminals 45, a control terminal support 48, a first conductive member 5, a second conductive member 6 and a sealing resin 8.

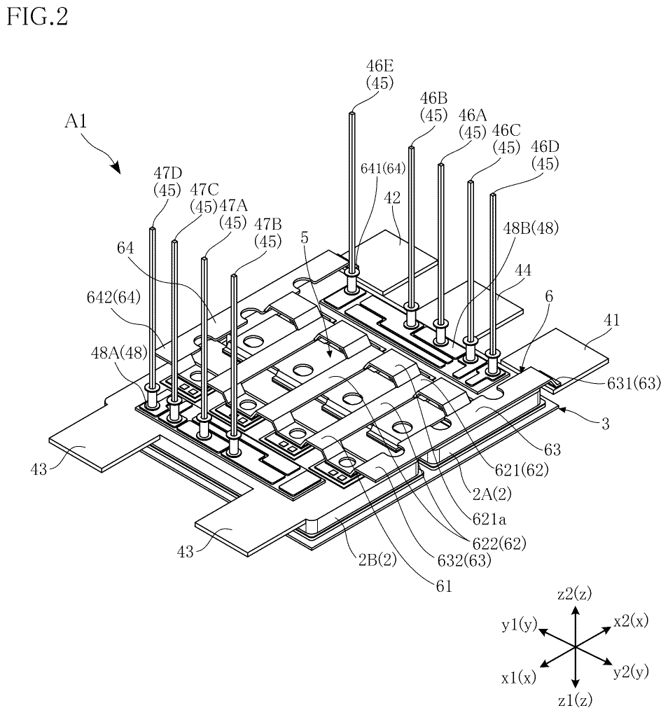

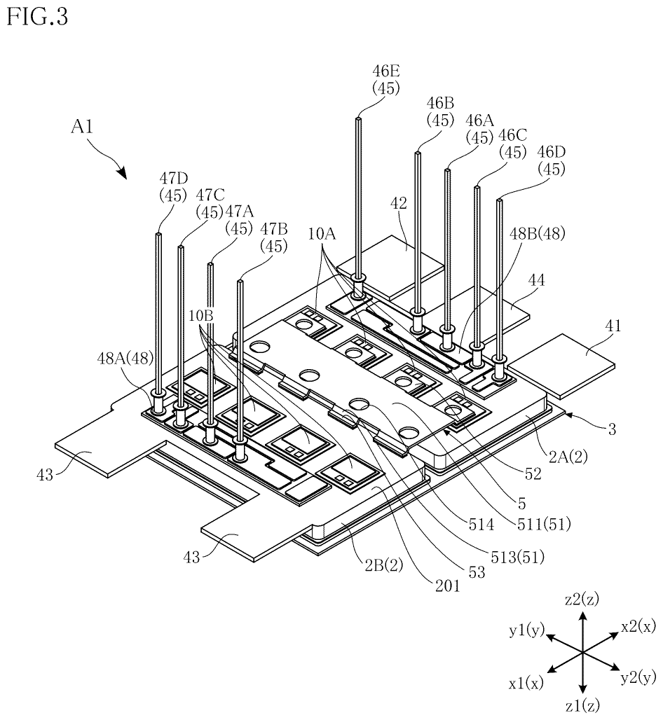

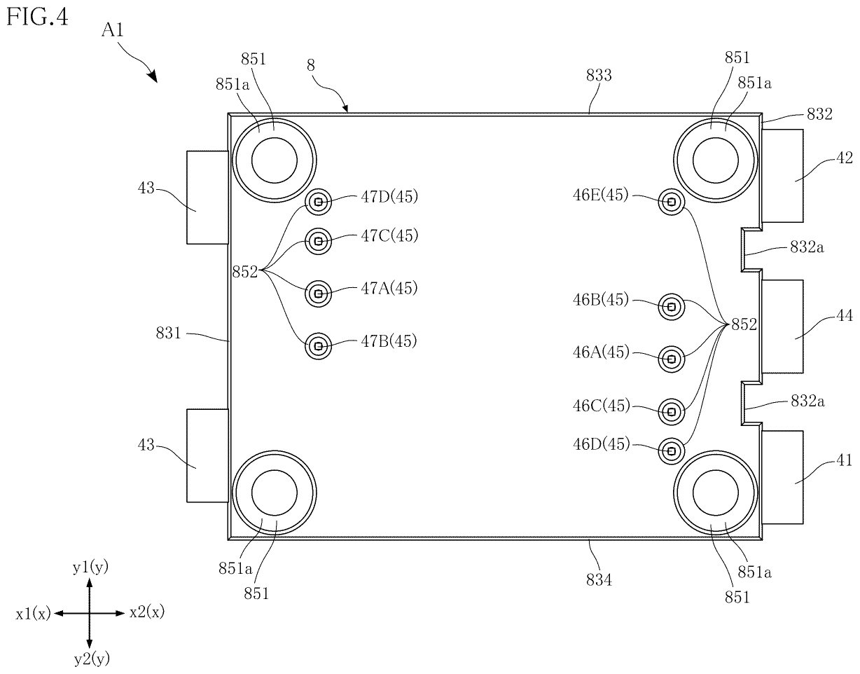

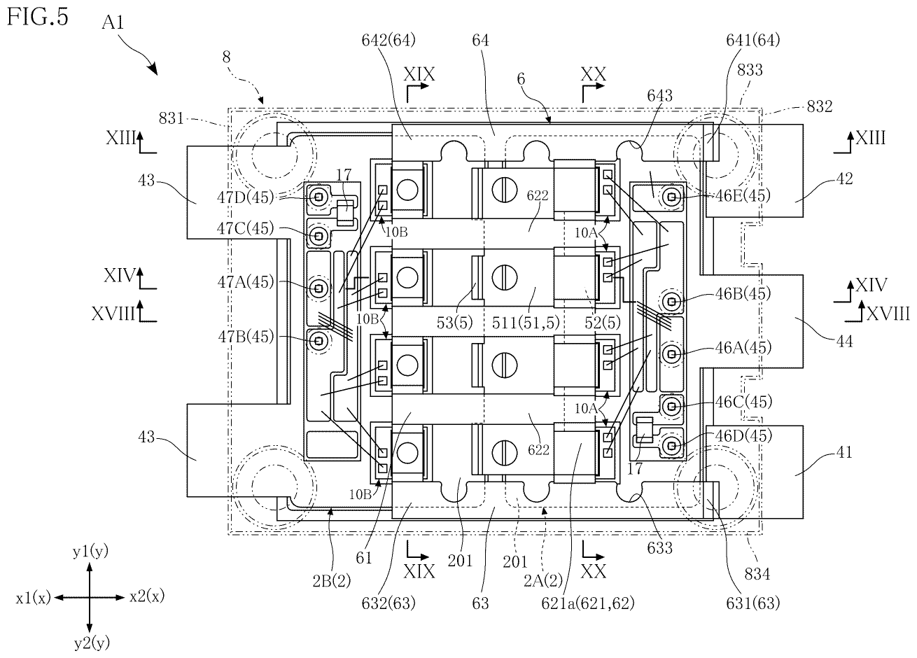

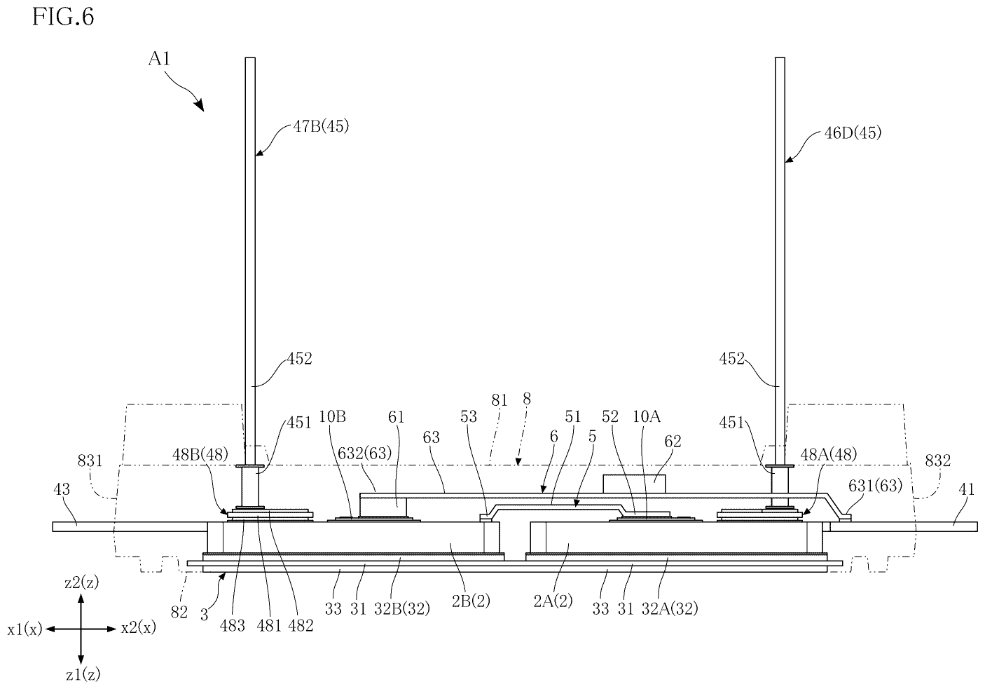

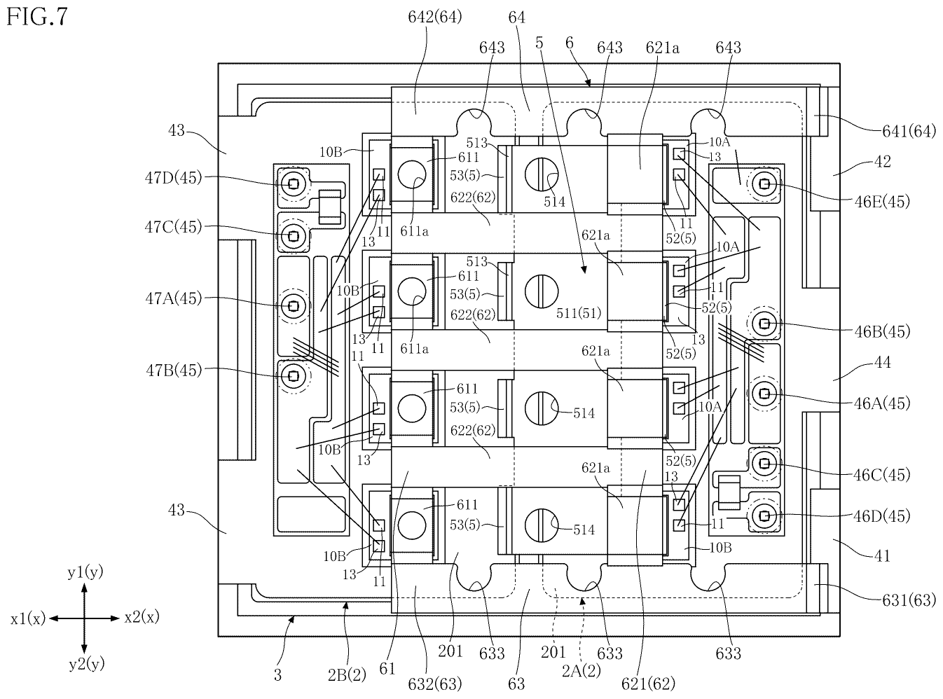

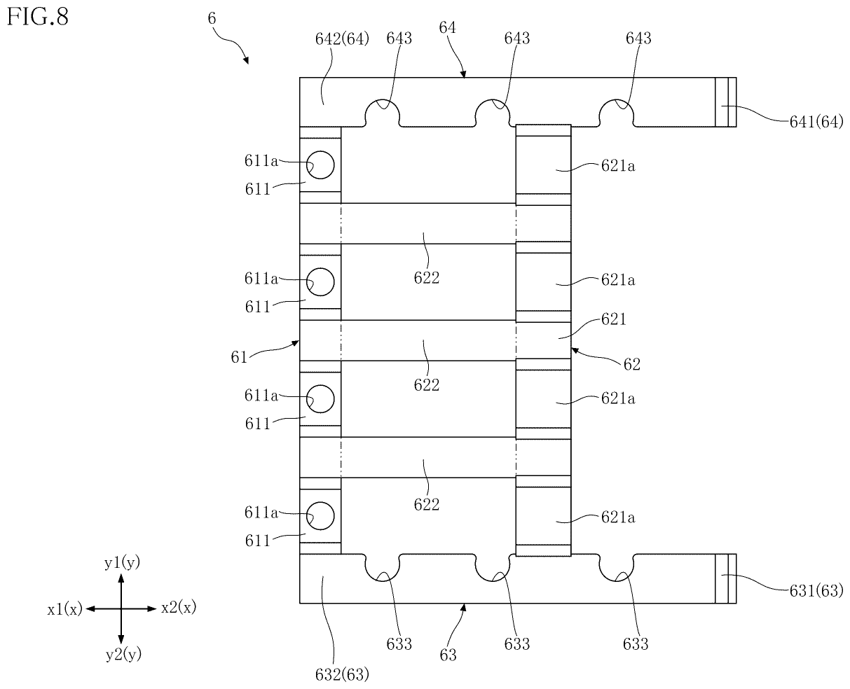

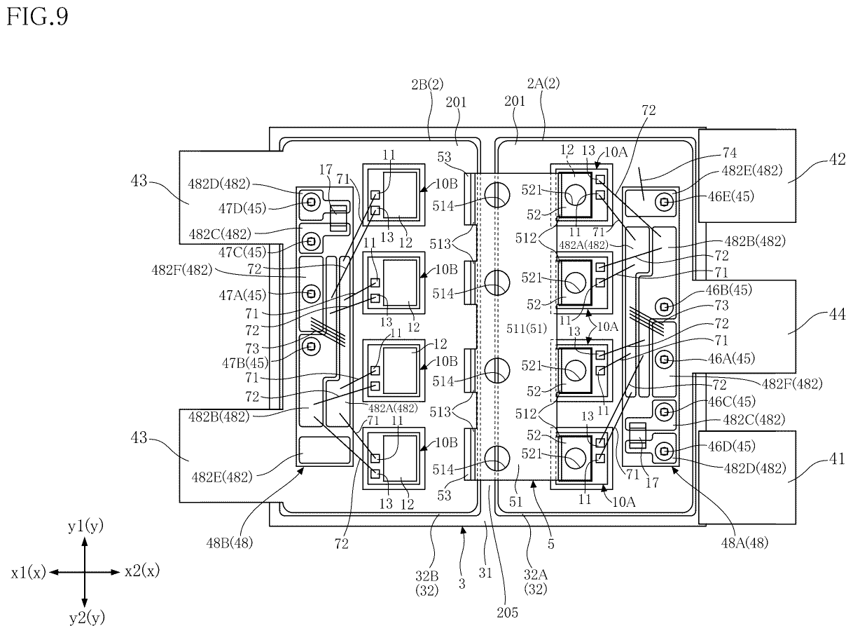

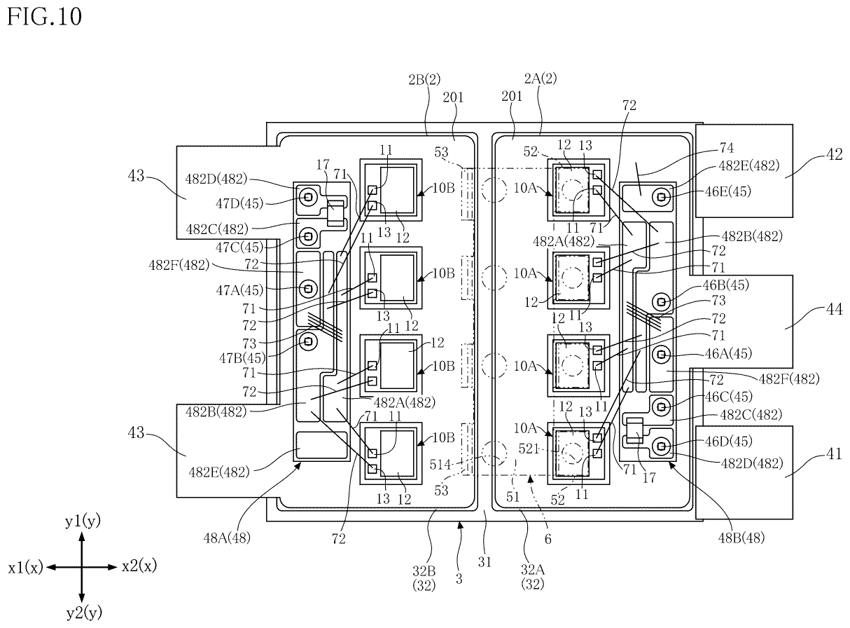

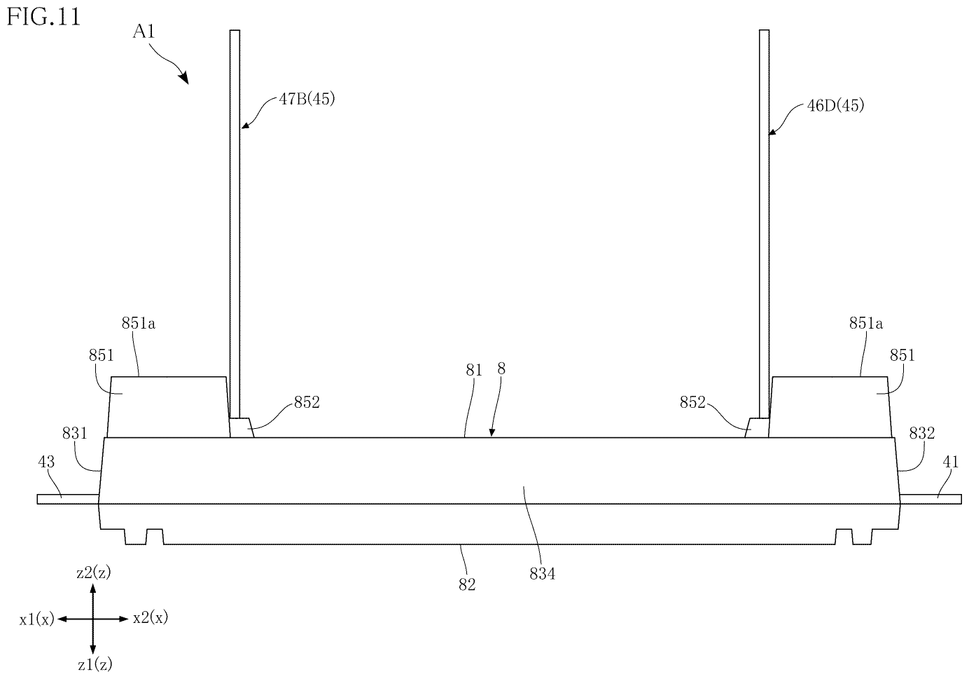

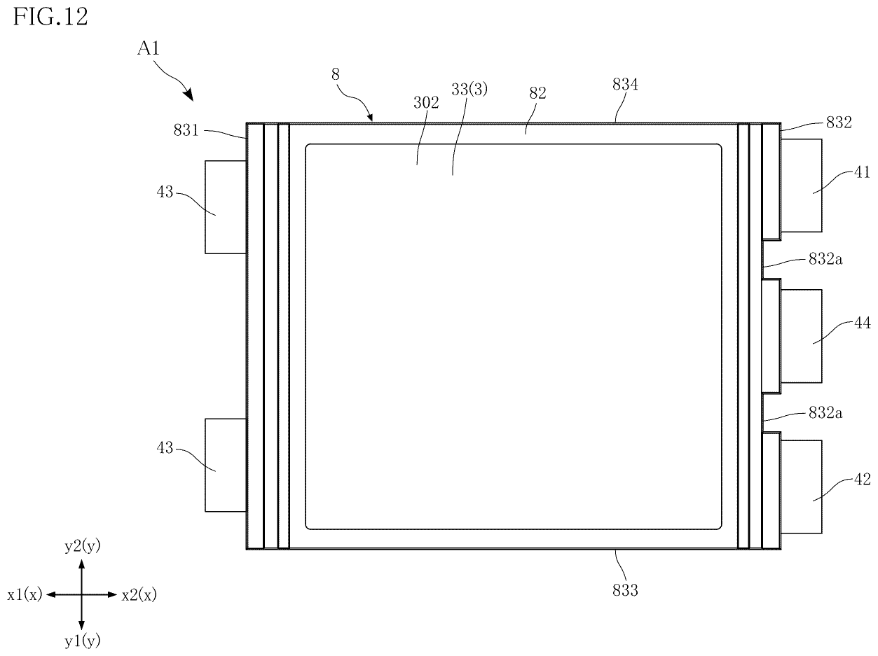

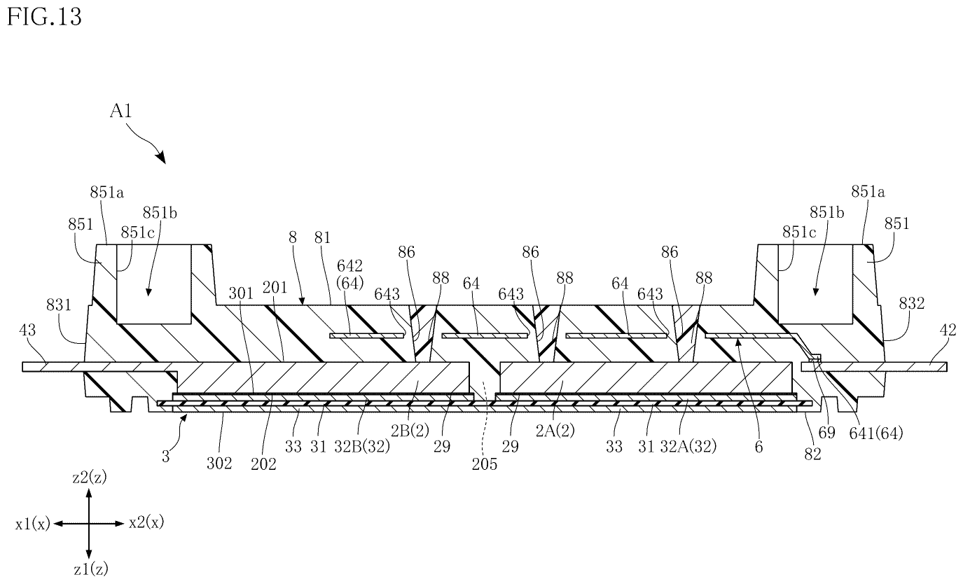

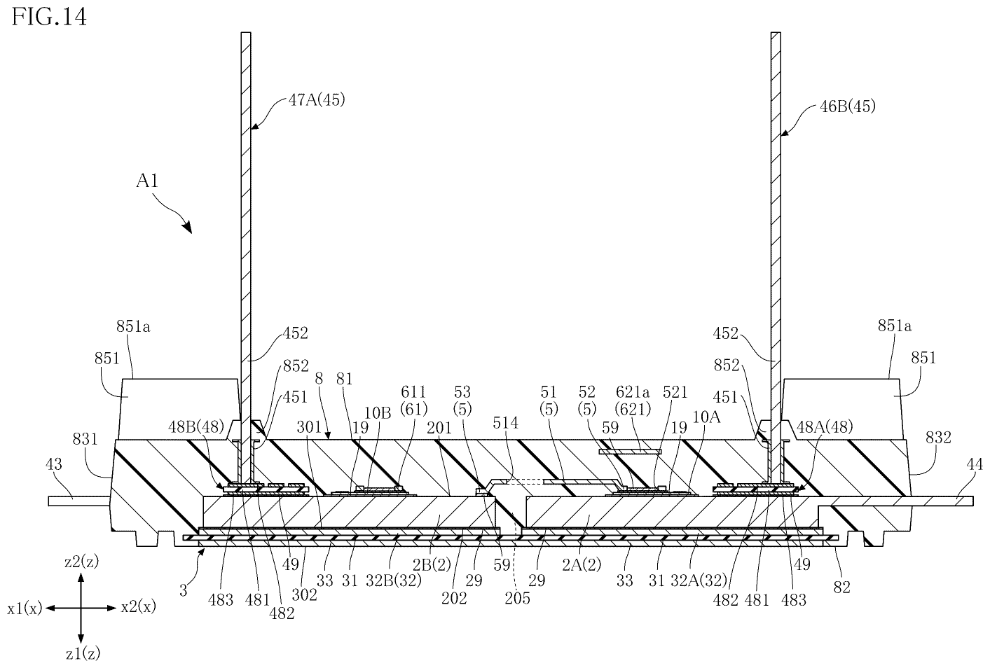

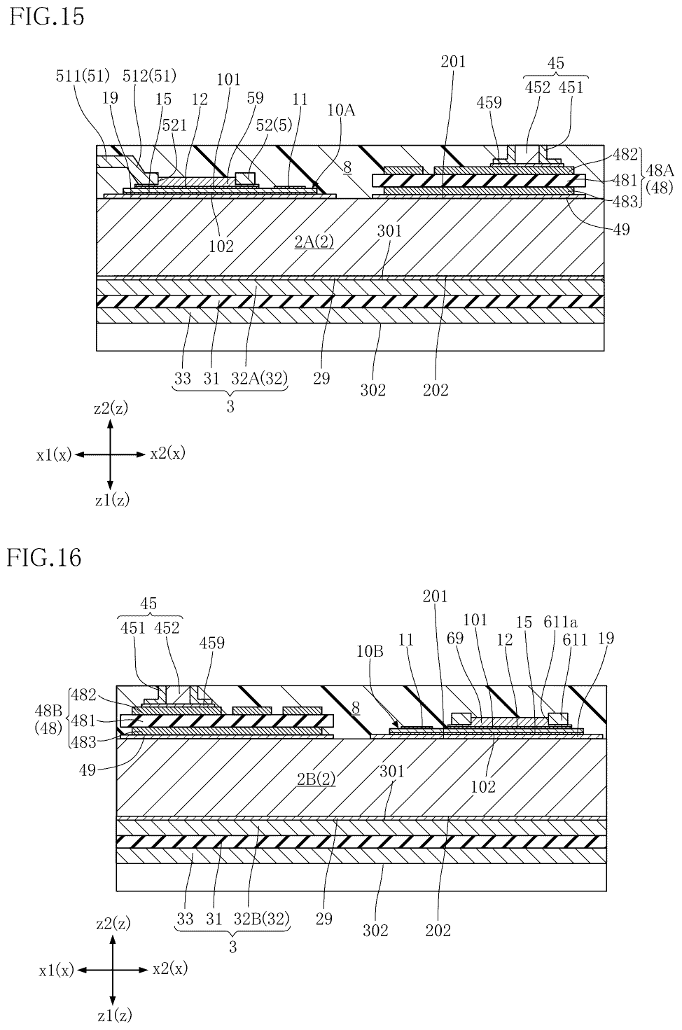

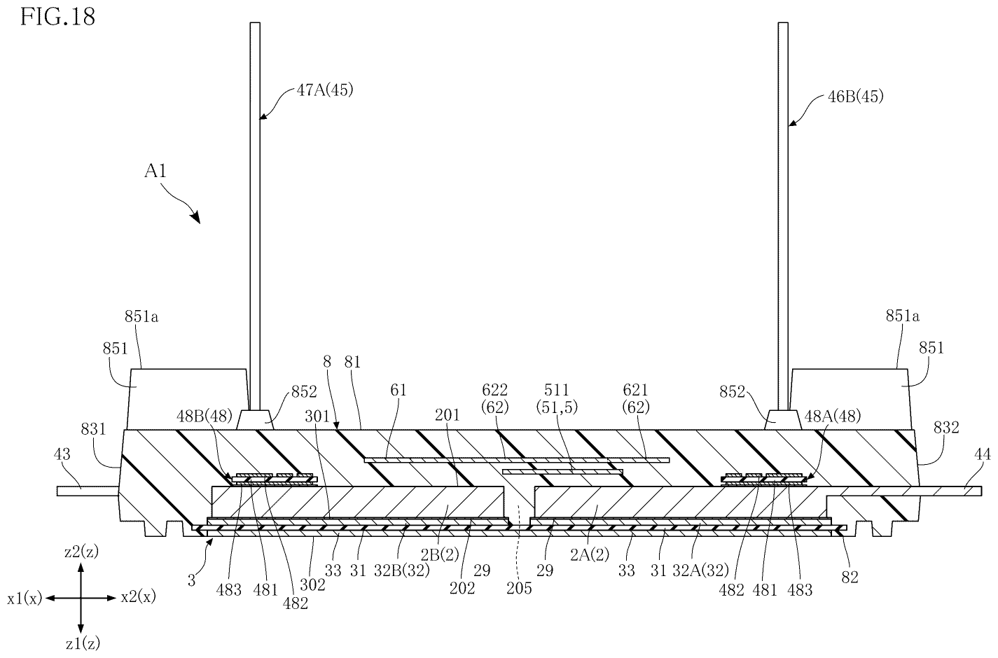

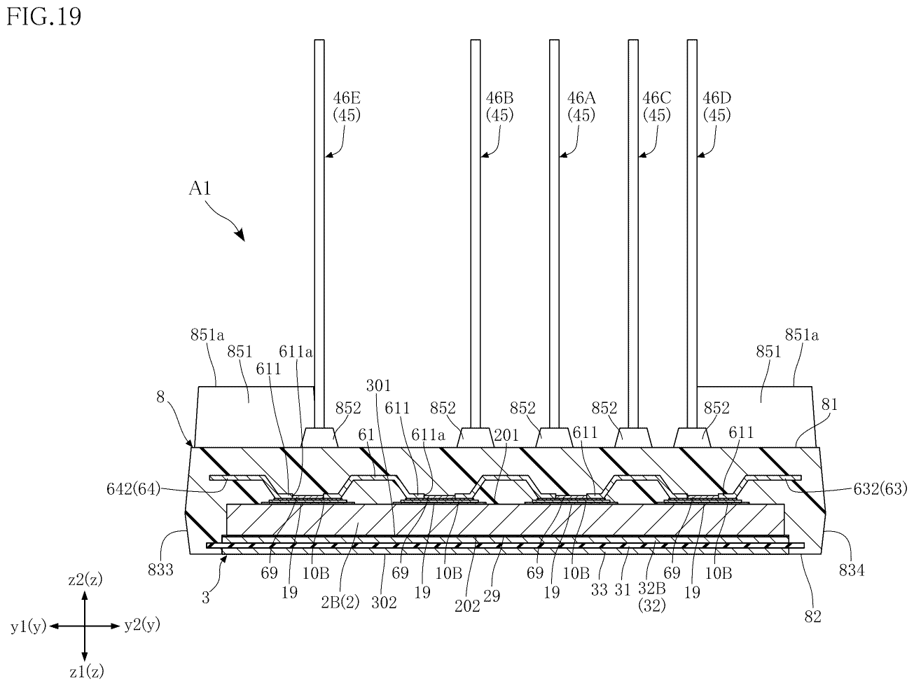

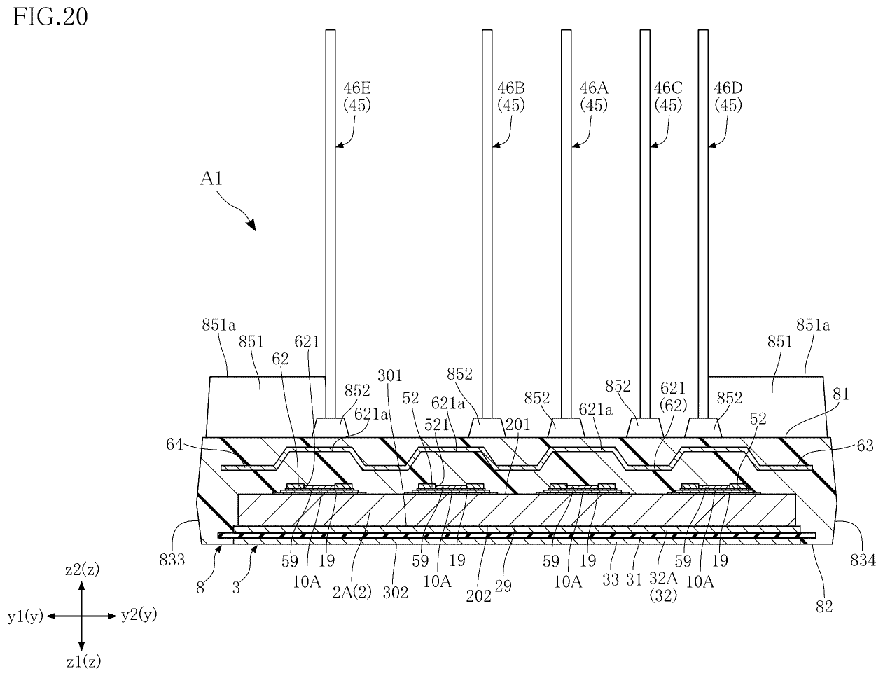

FIG. 1 is a perspective view of a semiconductor device A1. FIG. 2 is a perspective view corresponding to FIG. 1, from which the sealing resin 8 is omitted. FIG. 3 is a perspective view corresponding to FIG. 2, from which the first conductive member 5 is omitted. FIG. 4 is a plan view of the semiconductor device A1. FIG. 5 is a plan view corresponding to FIG. 4, in which the sealing resin 8 is indicated by imaginary lines. FIG. 6 is a right side view of the semiconductor device A1, in which the sealing resin 8 is indicated by imaginary lines. FIG. 7 is a partial enlarged view in which a portion of FIG. 5 is enlarged, with the sealing resin omitted. FIG. 8 is a plan view of the second conductive member 6. FIG. 9 is a plan view corresponding to FIG. 5, from which the sealing resin 8 and the second conductive member 6 are omitted. FIG. 10 is a plan view corresponding to FIG. 9, in which the first conductive member 5 is indicated by imaginary lines. FIG. 11 is a right side view of the semiconductor device A1. FIG. 12 is a bottom view of the semiconductor device A1. FIG. 13 is a sectional view taken along line XIII-XIII in FIG. 5. FIG. 14 is a sectional view taken along line XIV-XIV in FIG. 5. FIGS. 15 to 17 are partial enlarged views in which a portion of FIG. 14 is enlarged. FIG. 18 is a sectional view taken along line XVIII-XVIII in FIG. 5. FIG. 19 is a sectional view taken along line XIX-XIX in FIG. 5. FIG. 20 is a sectional view taken along line XX-XX in FIG. 5.

For the convenience of description, three mutually orthogonal directions (an x direction, a y direction, and a z direction) will be referred to. The z direction is, for example, the thickness direction of the semiconductor device A1. The x direction is the horizontal direction in a plan view (see FIG. 4) of the semiconductor device A1. The y direction is the vertical direction in a plan view (see FIG. 4) of the semiconductor device A1. In the description below, “in plan view” means as viewed in the z direction. The x direction is an example of a “first direction”, and the y direction is an example of a “second direction”.

Each of the first semiconductor elements 10A and the second semiconductor elements 10B is an electronic component as a core for the function of the semiconductor device A1. The constituent material of the first semiconductor elements 10A and the second semiconductor elements 10B is, for example, a semiconductor material mainly composed of SiC (silicon carbide). The semiconductor material is not limited to SiC and may be Si (silicon), GaN (gallium nitride) or C (diamond), etc. Each of the first semiconductor elements 10A and the second semiconductor elements 10B is a power semiconductor chip having a switching function, such as a MOSFET (Metal Oxide Semiconductor Field Effect Transistor). The first semiconductor elements 10A and the second semiconductor elements 10B are MOSFETs in the present embodiment, but are not limited to these and may be other transistors such as IGBTs (Insulated Gate Bipolar Transistors). The first semiconductor elements 10A and the second semiconductor elements 10B are all identical with each other. Each of the first semiconductor elements 10A and the second semiconductor elements 10B is, for example, an n-channel MOSFET, but may be a p-channel MOSFET.

As shown in FIGS. 15 and 16, each of the first semiconductor elements 10A and the second semiconductor elements 10B has an element obverse surface 101 and an element reverse surface 102. In each of the first semiconductor elements 10A and the second semiconductor elements 10B, the element obverse surface 101 and the element reverse surface 102 are spaced apart from each other in the z direction. The element obverse surface 101 faces in the z2 direction, and the element reverse surface 102 faces in the z1 direction.

In the present embodiment, the semiconductor device A1 includes four first semiconductor elements 10A and four second semiconductor elements 10B. However, the number of first semiconductor elements 10A and the number of second semiconductor elements 10B are not limited to this configuration, and may be changed as appropriate in accordance with the performance required of the semiconductor device A1. In the example shown in FIGS. 9 and 10, four each of the first semiconductor elements 10A and the second semiconductor elements 10B are provided. The number of first semiconductor elements 10A and the number of second semiconductor elements 10B may be two, three, or five or more. The number of first semiconductor elements 10A and the number of second semiconductor elements 10B may be the same or may be different. The number of first semiconductor elements 10A and the number of second semiconductor elements 10B are determined based on the current carrying capacity of the semiconductor device A1.

The semiconductor device A1 may be configured as a half-bridge type switching circuit. In this case, in the semiconductor device A1, the first semiconductor elements 10A constitute the upper arm circuit, and the second semiconductor elements 10B constitute the lower arm circuit. In the upper arm circuit, the first semiconductor elements 10A are connected in parallel with each other. In the lower arm circuit, the second semiconductor elements 10B are connected in parallel with each other. Each first semiconductor element 10A and a relevant one of the second semiconductor elements 10B are connected in series to form a bridge layer.

As shown in FIGS. 9, 10 and 20, each of the first semiconductor elements 10A is mounted on the conductive substrate 2. In the example shown in FIGS. 9 and 10, the first semiconductor elements 10A may be aligned in the y direction and are spaced apart from each other. Each first semiconductor element 10A is conductively bonded to the conductive substrate 2 (the first conductive portion 2A, described later) via a conductive bonding material 19. With the first semiconductor elements 10A bonded to the first conductive portion 2A, the element reverse surfaces 102 face the first conductive portion 2A.

As shown in FIGS. 9, 10 and 19, each of the second semiconductor elements 10B is mounted on the conductive substrate 2. In the example shown in FIGS. 9 and 10, the second semiconductor elements 10B may be aligned in the y direction and are spaced apart from each other. Each second semiconductor element 10B is conductively bonded to the conductive substrate 2 (the second conductive portion 2B, described later) via a conductive bonding material 19. With the second semiconductor elements 10B bonded to the second conductive portion 2B, the element reverse surfaces 102 face the second conductive portion 2B. As will be understood from FIG. 10, the first semiconductor elements 10A and the second semiconductor elements 10B overlap with each other as viewed in the x direction, but may not overlap with each other.

Each of the first semiconductor elements 10A and the second semiconductor elements 10B has a first obverse electrode 11, a second obverse electrode 12, a third obverse electrode 13, and a reverse electrode 15. The configurations of the first obverse electrode 11, the second obverse electrode 12, the third obverse electrode 13 and the reverse electrode 15 described below are common to the first semiconductor elements 10A and the second semiconductor elements 10B. The first obverse electrode 11, the second obverse electrode 12, and the third obverse electrode 13 are provided on the element obverse surface 101. The first obverse electrode 11, the second obverse electrode 12 and the third obverse electrode 13 are insulated from each other by an insulating film, not shown. The reverse electrode 15 is provided on the element reverse surface 102.

The first obverse electrode 11 is, for example, a gate electrode, through which a drive signal (e.g., gate voltage) for driving the first semiconductor element 10A (the second semiconductor element 10B) is input. In each first semiconductor element 10A (each second semiconductor element 10B), the second obverse electrode 12 is, for example, a source electrode, through which a source current flows. The third obverse electrode 13 is, for example, a source sense electrode, through which a source current flows. The reverse electrode 15 is, for example, a drain electrode, through which a drain current flows. The reverse electrode 15 covers the entire area (or almost the entire area) of the element reverse surface 102. The reverse electrode 15 is formed by Ag (silver) plating, for example.

Each of the first semiconductor elements 10A (the second semiconductor elements 10B) switches between a conducting state and a disconnected state in response to a drive signal (gate voltage) inputted to the first obverse electrode 11 (the gate electrode). In the conducting state, a current flows from the reverse electrode 15 (the drain electrode) to the second obverse electrode 12 (the source electrode). In the disconnected state, this current does not flow. That is, each first semiconductor element 10A (each second semiconductor element 10B) performs a switching operation. The semiconductor device A1 uses the switching function of the first semiconductor elements 10A and the second semiconductor elements 10B to convert the DC voltage inputted between the single fourth terminal 44 and the two, i.e., the first and the second terminals 41 and 42 into e.g. an AC voltage and outputs the AC voltage from the third terminals 43.

As shown in FIGS. 5, 9 and 10, the semiconductor device A1 includes thermistors 17. The thermistors 17 are used as a temperature detection sensor.

The conductive substrate 2 supports the first semiconductor elements 10A and the second semiconductor elements 10B. The conductive substrate 2 is bonded on the support substrate 3 via a conductive bonding material 29. The conductive substrate 2 is, for example, rectangular in plan view. The conductive substrate 2, together with the first conductive member 5 and the second conductive member 6, constitutes paths for the main circuit current switched by the first semiconductor elements 10A and the second semiconductor elements 10B.

The conductive substrate 2 includes a first conductive portion 2A and a second conductive portion 2B. Each of the first conductive portion 2A and the second conductive portion 2B is a plate made of a metal. The metal may be Cu (copper) or a copper alloy, for example. The first conductive portion 2A and the second conductive portion 2B, together with the first terminal 41, the second terminal 42, the third terminals 43 and the fourth terminal 44, constitute conduction paths to the first semiconductor elements 10A and the second semiconductor elements 10B. As shown in FIGS. 13 to 20, each of the first conductive portion 2A and the second conductive portion 2B is bonded on the support substrate 3 via a conductive bonding material 29. Each of the first semiconductor elements 10A is bonded to the first conductive portion 2A via a conductive bonding material 19. Each of the second semiconductor elements 10B is bonded to the second conductive portion 2B via a conductive bonding material 19. The constituent material of the conductive bonding materials 19 and the conductive bonding materials 29 is not particularly limited, and may be solder, metal paste or sintered metal, for example. As shown in FIGS. 3, 9, 10, 13 and 14, the first conductive portion 2A and the second conductive portion 2B are spaced apart from each other in the x direction. In the example shown in these figures, the first conductive portion 2A is located in the x2 direction from the second conductive portion 2B. Each of the first conductive portion 2A and the second conductive portion 2B is, for example, rectangular in plan view. The first conductive portion 2A and the second conductive portion 2B overlap with each other as viewed in the x direction. Each of the first conductive portion 2A and the second conductive portion 2B may have a dimension of 15 mm to 25 mm in the x direction, a dimension of 30 mm to 40 mm in the y direction, and a dimension of 1.0 mm to 5.0 mm (preferably, about 2.0 mm) in the z direction, for example.

The conductive substrate 2 has an obverse surface 201 and a reverse surface 202. As shown in FIGS. 13, 14 and 18 to 20, the obverse surface 201 and the reverse surface 202 are spaced apart from each other in the z direction. The obverse surface 201 faces in the z2 direction, and the reverse surface 202 faces in the z1 direction. The obverse surface 201 is constituted of the upper surface of the first conductive portion 2A and the upper surface of the second conductive portion 2B. The reverse surface 202 is constituted of the lower surface of the first conductive portion 2A and the lower surface of the second conductive portion 2B. The reverse surface 202 is bonded to the support substrate 3 such that it faces the support substrate 3.

The support substrate 3 supports the conductive substrate 2. The support substrate 3 is provided by an AMB (Active Metal Brazing) substrate. The support substrate 3 includes an insulating layer 31, a first metal layer 32, and a second metal layer 33.

The insulating layer 31 may be ceramic having excellent thermal conductivity, for example. Examples of such ceramic include SiN (silicon nitride). The insulating layer 31 is not limited to ceramic and may be a sheet of an insulating resin, for example. The insulating layer 31 is, for example, rectangular in plan view.

The first metal layer 32 is formed on the upper surface (the surface facing in the z2 direction) of the insulating layer 31. The constituent material of the first metal layer 32 contains Cu, for example. The constituent material may contain Al (aluminum) rather than Cu. The first metal layer 32 includes a first portion 32A and a second portion 32B. The first portion 32A and the second portion 32B are spaced apart from each other in the x direction. The first portion 32A is located on the x2 side of the second portion 32B. The first conductive portion 2A is bonded to and supported by the first portion 32A. The second conductive portion 2B is bonded to and supported by the second portion 32B. Each of the first portion 32A and the second portion 32B is, for example, rectangular in plan view.

The second metal layer 33 is formed on the lower surface (the surface facing in the z1 direction) of the insulating layer 31. The constituent material of the second metal layer 33 is the same as the constituent material of the first metal layer 32. In the example shown in FIG. 11, the lower surface (the bottom surface 302, described later) of the second metal layer 33 may be exposed from the sealing resin 8. The lower surface may not be exposed from the sealing resin 8 and may be covered with the sealing resin 8. The second metal layer 33 overlaps with both the first portion 32A and the second portion 32B in plan view.

As shown in FIGS. 13 to 20, the support substrate 3 has a support surface 301 and a bottom surface 302. The support surface 301 and the bottom surface 302 are spaced apart from each other in the z direction. The support surface 301 faces in the z2 direction, and the bottom surface 302 faces in the z1 direction. As shown in FIG. 12, the bottom surface 302 is exposed from the sealing resin 8. The support surface 301 is the upper surface of the first metal layer 32 and constituted of the upper surface of the first portion 32A and the upper surface of the second portion 32B. The support surface 301 faces the conductive substrate 2, and the conductive substrate 2 is bonded to the support surface 301. The bottom surface 302 is the lower surface of the second metal layer 33. A heat dissipation member (e.g., a heat sink), not shown, can be attached to the bottom surface 302. The dimension of the support substrate 3 in the z direction (the distance from the support surface 301 to the bottom surface 302 in the z direction) is, for example, 0.7 mm to 2.0 mm.

Each of the first terminal 41, the second terminal 42, the third terminals 43, and the fourth terminal 44 is provided by a plate made of a metal. The constituent material of the metal plate is, for example, Cu or a Cu alloy. In the example shown in FIGS. 1 to 5, 9, 10 and 12, the semiconductor device A1 has one each of the first terminal 41, the second terminal 42 and the fourth terminal 44, and two third terminals 43.

A DC voltage to be converted is inputted to the first terminal 41, the second terminal 42 and the fourth terminal 44. The fourth terminal 44 is a positive electrode (P terminal), and each of the first terminal 41 and the second terminal 42 is a negative electrode (N terminal). The AC voltage converted by the first semiconductor elements 10A and the second semiconductor elements 10B is outputted from the third terminals 43. Each of the first terminal 41, the second terminal 42, the third terminals 43 and the fourth terminal 44 includes a portion covered with the sealing resin 8 and a portion exposed from the sealing resin 8.

As shown in FIG. 14, the fourth terminal 44 is formed integrally with the first conductive portion 2A. Unlike this configuration, the fourth terminal 44 may be provided separately from the first conductive portion 2A and conductively bonded to the first conductive portion 2A. As shown in FIGS. 9 and 10, the fourth terminal 44 is located on the x2 side with respect to the second semiconductor elements 10B and the second conductive portion 2B (the conductive substrate 2). The fourth terminal 44 is electrically connected to the first conductive portion 2A and also electrically connected to the reverse electrode 15 (the drain electrode) of each first semiconductor element 10A via the first conductive portion 2A.

As shown in FIG. 9, the first terminal 41 and the second terminal 42 are spaced apart from the first conductive portion 2A. As shown in FIGS. 5 and 7, the second conductive member 6 is bonded to the first terminal 41 and the second terminal 42. As shown in FIGS. 5 and 9, the first terminal 41 and the second terminal 42 are located on the x2 side with respect to the first semiconductor elements 10A and the first conductive portion 2A (the conductive substrate 2). The first terminal 41 and the second terminal 42 are electrically connected to the second conductive member 6 and also electrically connected to the second obverse electrode 12 (the source electrode) of each second semiconductor element 10B via the second conductive member 6.

As shown in FIGS. 1 to 5 and 12, in the semiconductor device A1, the first terminal 41, the second terminal 42 and the fourth terminal 44 protrude from the sealing resin 8 in the x2 direction. The first terminal 41, the second terminal 42 and the fourth terminal 44 are spaced apart from each other. The first terminal 41 and the second terminal 42 are located opposite to each other with the fourth terminal 44 interposed therebetween in the y direction. The first terminal 41 is located on the y2 side of the fourth terminal 44, and the second terminal 42 is located on the y1 side of the fourth terminal 44. The first terminal 41, the second terminal 42 and the fourth terminal 44 overlap with each other as viewed in the y direction.

As will be understood from FIGS. 9, 10 and 13, the two third terminals 43 are integrally formed with the second conductive portion 2B. Unlike this configuration, the third terminals 43 may be provided separately from the second conductive portion 2B and conductively bonded to the second conductive portion 2B. As shown in FIG. 9, the two third terminals 43 are located on the x1 side with respect to the second semiconductor elements 10B and the second conductive portion 2B (the conductive substrate 2). Each third terminal 43 is electrically connected to the second conductive portion 2B and also electrically connected to the reverse electrode (the drain electrode) of each second semiconductor element 10B via the second conductive portion 2B. Note that the number of third terminals 43 is not limited to two, and may be one, or three or more. When only one third terminal 43 is provided, the third terminal 43 is preferably connected to the middle part in the y direction of the second conductive portion 2B.

Each of the control terminals 45 is a pin-shaped terminal for controlling the first semiconductor elements 10A and the second semiconductor elements 10B. The control terminals 45 include a plurality of first control terminals 46A to 46E and a plurality of second control terminals 47A to 47D. The first control terminals 46A to 46E are used to control the first semiconductor elements 10A, for example. The second control terminals 47A to 47D are used to control the second semiconductor elements 10B, for example.

The first control terminals 46A to 46E are arranged at intervals in the y direction. As shown in FIGS. 9 and 14, the first control terminals 46A to 46E are supported on the first conductive portion 2A via the control terminal support 48 (the first support portion 48A, described later). As shown in FIGS. 5 and 9, the first control terminals 46A to 46E are located between the first semiconductor elements 10A and the first, the second and the fourth terminals 41, 42 and 44 in the x direction.

The first control terminal 46A is a terminal (a gate terminal) for inputting a drive signal for the first semiconductor elements 10A. A drive signal for driving the first semiconductor elements 10A is inputted (e.g., a gate voltage is applied) to the first control terminal 46A.

The first control terminal 46B is a terminal (a source sense terminal) for detecting a source signal of the first semiconductor elements 10A. The voltage applied to the second obverse electrode 12 (the source electrode) of each first semiconductor element 10A (the voltage corresponding to the source current) is detected from the first control terminal 46B.

The first control terminal 46C and the first control terminal 46D are terminals electrically connected to a thermistor 17.

The first control terminal 46E is a terminal (a drain sense terminal) for detecting a drain signal of the first semiconductor elements 10A. The voltage applied to the reverse electrode 15 (the drain electrode) of each first semiconductor element 10A (the voltage corresponding to the drain current) is detected from the first control terminal 46E.

The second control terminals 47A to 47D are arranged at intervals in the y direction. As shown in FIGS. 9 and 14, the second control terminals 47A to 47D are supported on the second conductive portion 2B via the control terminal support 48 (the second support portion 48B, described later). As shown in FIGS. 5 and 9, the second control terminals 47A to 47D are located between the second semiconductor elements 10B and the two third terminals 43 in the x direction.

The second control terminal 47A is a terminal (a gate terminal) for inputting a drive signal for the second semiconductor elements 10B. A drive signal for driving the second semiconductor elements 10B is inputted (e.g., a gate voltage is applied) to the second control terminal 47A. The second control terminal 47B is a terminal (a source sense terminal) for detecting a source signal of the second semiconductor elements 10B. The voltage applied to the second obverse electrode 12 (the source electrode) of each second semiconductor element 10B (the voltage corresponding to the source current) is detected from the second control terminal 47B. The second control terminal 47C and the second control terminal 47D are terminals electrically connected to a thermistor 17.

Each of the control terminals 45 (the first control terminals 46A to 46E and the second control terminals 47A to 47D) includes a holder 451 and a metal pin 452.

The holders 451 are made of an electrically conductive material. As shown in FIGS. 15 and 16, the holders 451 are bonded to the control terminal support 48 (the first metal layer 482, described later) via a conductive bonding material 459. Each holder 451 includes a cylindrical portion, an upper flange portion, and a lower flange portion. The upper flange portion is connected to the upper part of the cylindrical portion, and the lower flange portion is connected to the lower part of the cylindrical portion. A metal pin 452 is inserted in at least the upper flange portion and the cylindrical portion of each holder 451. The holder 451 is covered with the sealing resin 8 (the second protrusion 852, described later).

The metal pins 452 are bar-shaped members extending in the z direction. The metal pins 452 are supported by being press-fitted into the holders 451. The metal pins 452 are electrically connected to the control terminal support 48 (the first metal layer 482, described later) at least via the holders 451. When the lower ends (the ends on the z1 side) of the metal pins 452 are in contact with the conductive bonding material 459 within the through-holes of the holders 451 as in the example shown in FIGS. 15 and 16, the metal pins 452 are electrically connected to the control terminal support 48 via the conductive bonding material 459.

The control terminal support 48 supports the plurality of control terminals 45. The control terminal support 48 is interposed between the obverse surface 201 (the conductive substrate 2) and the control terminals 45 in the z direction.

The control terminal support 48 includes a first support portion 48A and a second support portion 48B. The first support portion 48A is disposed on the first conductive portion 2A of the conductive substrate 2 and supports the first control terminals 46A to 46E of the control terminals 45. As shown in FIG. 15, the first support portion 48A is bonded to the first conductive portion 2A via a bonding material 49. The bonding material 49 may be electrically conductive or insulating, and solder may be used, for example. The second support portion 48B is disposed on the second conductive portion 2B of the conductive substrate 2 and supports the second control terminals 47A to 47D of the control terminals 45. As shown in FIG. 16, the second support portion 48B is bonded to the second conductive portion 2B via a bonding material 49.

The control terminal support 48 (each of the first support portion 48A and the second support portion 48B) is provided by a DBC (Direct Bonded Copper) substrate, for example. The control terminal support 48 includes an insulating layer 481, a first metal layer 482 and a second metal layer 483 laminated on top of each other.

The insulating layer 481 is made of ceramic, for example. The insulating layer 481 may be rectangular in plan view.

As shown in FIGS. 15 and 16, the first metal layer 482 is formed on the upper surface of the insulating layer 481. Each control terminal 45 stands on the first metal layer 482. The first metal layer 482 is Cu or a Cu alloy, for example. As shown in FIG. 9, the first metal layer 482 includes a first portion 482A, a second portion 482B, a third portion 482C, a fourth portion 482D, a fifth portion 482E, and a sixth portion 482F. The first portion 482A, the second portion 482B, the third portion 482C, the fourth portion 482D, the fifth portion 482E, and the sixth portion 482F are spaced apart and insulated from each other.

The first portion 482A, to which a plurality of wires 71 are bonded, is electrically connected to the first obverse electrodes 11 (gate electrodes) of the first semiconductor elements 10A (the second semiconductor elements 10B) via the wires 71. The first portion 482A and the sixth portion 482F are connected to each other via a plurality of wires 73. Thus, the sixth portion 482F is electrically connected to the first obverse electrodes 11 (gate electrodes) of the first semiconductor elements 10A (the second semiconductor elements 10B) via the wires 73 and the wires 71. As shown in FIG. 9, the first control terminal 46A is bonded to the sixth portion 482F of the first support portion 48A, and the second control terminal 47A is bonded to the sixth portion 482F of the second support portion 48B.

The second portion 482B, to which a plurality of wires 72 are bonded, is electrically connected to the second obverse electrodes 12 (source electrodes) of the first semiconductor elements 10A (the second semiconductor elements 10B) via the wires 72. As shown in FIG. 9, the first control terminal 46B is bonded to the second portion 482B of the first support portion 48A, and the second control terminal 47B is bonded to the second portion 482B of the second support portion 48B.

A thermistor 17 is bonded to the third portion 482C and the fourth portion 482D. As shown in FIG. 9, the first control terminals 46C and 46D are bonded to the third portion 482C and the fourth portion 482D, respectively, of the first support portion 48A. The second control terminals 47C and 47D are bonded to the third portion 482C and the fourth portion 482D, respectively, of the second support portion 48B.

The fifth portion 482E of the first support portion 48A, to which a wire 74 is bonded, is electrically connected to the first conductive portion 2A via the wire 74. As shown in FIG. 9, the first control terminal 46E is bonded to the fifth portion 482E of the first support portion 48A. The fifth portion 482E of the second support portion 48B is not electrically connected to other components. Each of the wires 71 to 74 is, for example, a bonding wire. The constituent material of the wires 71 to 74 includes one of Au (gold), Al or Cu, for example.

As shown in FIG. 15, 16, the second metal layer 483 is formed on the lower surface of the insulating layer 481. As shown in FIG. 15, the second metal layer 483 of the first support portion 48A is bonded to the first conductive portion 2A via a bonding material 49. As shown in FIG. 16, the second metal layer 483 of the second support portion 48B is bonded to the second conductive portion 2B via a bonding material 49.

The first conductive member 5 and the second conductive member 6, together with the conductive substrate 2, constitute paths for the main circuit current switched by the first semiconductor elements 10A and the second semiconductor elements 10B. The first conductive member 5 and the second conductive member 6 are spaced apart from the obverse surface 201 (the conductive substrate 2) in the z2 direction and overlap with the obverse surface 201 in plan view. In the present embodiment, each of the first conductive member 5 and the second conductive member 6 is provided by a plate made of a metal. The metal may be Cu (copper) or a copper alloy, for example. Specifically, each of the first conductive member and the second conductive member 6 is a metal plate bent as appropriate.

The first conductive member 5 is connected to the second obverse electrode 12 (the source electrode) of each first semiconductor element 10A and the second conductive portion 2B to electrically connect the second obverse electrode 12 of each first semiconductor element 10A and the second conductive portion 2B to each other. The first conductive member 5 constitutes a path for the main circuit current switched by the first semiconductor elements 10A. As shown in FIGS. 7 and 9, the first conductive member 5 includes a first part 51, a plurality of first bond portions 52 and a plurality of second bond portions 53.

The first part 51 is a strip-shaped portion located between the first semiconductor elements 10A and the second conductive portion 2B in the x direction and elongated in the y direction in plan view. The first part 51 overlaps with both the first conductive portion 2A and the second conductive portion 2B in plan view and spaced apart from the obverse surface 201 toward the z2 side in the z direction. As shown in FIG. 18, the first part 51 is located in the z1 direction from the second strip 622, described later, of the second conductive member 6 and located closer to the obverse surface 201 (the conductive substrate 2) than is the second strip 622.

In the present embodiment, the first part 51 includes a flat section 511, a plurality of first bent sections 512 and a plurality of second bent sections 513. The flat section 511 is disposed in parallel to the obverse surface 201 and overlaps with both the first conductive portion 2A and the second conductive portion 2B in plan view. As used herein, being “in parallel” regarding the flat section 511 to the obverse surface 201 allows for manufacturing errors and may include the case where the obverse surface 201 and the flat section 511 are generally parallel to each other.

As shown in FIG. 9, the flat section 511 extends continuously in the y direction to correspond to the areas in which the first semiconductor elements 10A are arranged. In the present embodiment, the flat section 511 is formed with a plurality of first openings 514 as shown in FIGS. 7, 9 and 14. Each of the first openings 514 is a through-hole penetrating in the z direction (the plate thickness direction of the first part 51). The first openings 514 are arranged at intervals in the y2 direction. Each of the first openings 514 is provided to correspond to a respective one of the first semiconductor elements 10A. In the present embodiment, four first openings 514 are provided in the flat section 511, and the first openings 514 and the plurality of (four) first semiconductor elements 10A are at the same positions in the y direction.

In the present embodiment, as shown in FIGS. 9 and 14, each of the first openings 514 overlaps with a gap 205 between the first conductive portion 2A and the second conductive portion 2B in plan view. Further, each first opening 514 overlaps with the first conductive portion 2A in plan view. The first openings 514 are formed to facilitate the flow of the resin material between the upper side (z2 side) and the lower side (z1 side) at or near the first part 51 (the first conductive member 5) when the flowable resin material is injected to form the sealing resin 8.

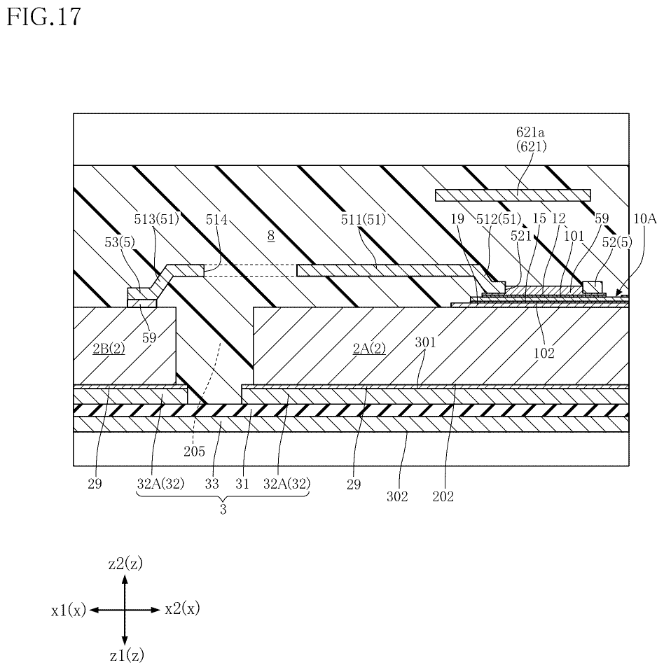

As shown in FIG. 9, the first bent sections 512 and the second bent sections 513 are connected to the flat section 511 and disposed correspondingly to the first semiconductor elements 10A. As shown in FIG. 17, each of the first bent sections 512 is connected to the end in the x2 direction of the flat section 511 and extends down in the z1 direction as proceeding in the x2 direction. Each of the second bent sections 513 is connected to the end in the x1 direction of the flat section 511 and extends down in the z1 direction as proceeding in the x1 direction.

As shown in FIG. 9, the first bond portions 52 and the second bond portions 53 are connected to the first part 51 and disposed to correspond to the first semiconductor elements 10A. Specifically, each of the first bond portions 52 is located in the x2 direction from the first part 51 and connected to one of the first bent sections 512. Each of the second bond portions 53 is located in the x1 direction from the first part 51 and connected to one of the second bent sections 513. As shown in FIGS. 15 and 17, each of the first bond portions 52 and the second obverse electrode 12 of a relevant one of the first semiconductor elements 10A are bonded to each other via a conductive bonding material 59. As shown in FIG. 17, each of the second bond portions 53 and the second conductive portion 2B are bonded to each other via a conductive bonding material 59. The constituent material of the conductive bonding materials 59 is not particularly limited, and may be solder, metal paste or sintered metal, for example. In the present embodiment, each of the first bond portions 52 is formed with an opening 521. Preferably, each opening 521 is formed to overlap with the middle part of a first semiconductor element 10A in plan view. The openings 521 are through-holes penetrating in the z direction, for example. The openings 521 may be used to position the first conductive member 5 relative to the conductive substrate 2. The shape in plan view of the openings 521 may be a perfect circle, or may be other shapes such as an ellipse or a rectangle.

The second conductive member 6 is connected to the second obverse electrode 12 (the source electrode) of each of the second semiconductor elements and the first and the second terminals 41 and 42 to electrically connect the second obverse electrode 12 of each second semiconductor element 10B and the first and the second terminals 41 and 42 to each other. The second conductive member 6 constitutes a path for the main circuit current switched by the second semiconductor elements 10B. The second conductive member 6 has a maximum dimension in the x direction of 25 mm to 40 mm, for example, and a maximum dimension in the y direction of 30 mm to 45 mm, for example. As shown in FIGS. 7 and 8, the second conductive member 6 includes a first wiring portion 61, a second wiring portion 62, a third wiring portion 63, and a fourth wiring portion 64.

The first wiring portion 61 is a strip-shaped portion extending in the y direction in plan view. As will be understood from FIG. 7, the first wiring portion 61 overlaps with the second semiconductor elements 10B in plan view. As shown in FIG. 19, the first wiring portion 61 is connected to each of the second semiconductor elements 10B.

The first wiring portion 61 has a plurality of recessed regions 611. As shown in FIG. 19, each recessed region 611 protrudes in the z1 direction relative to the rest of the first wiring portion 61. Each recessed region 611 is bonded to one of the second semiconductor elements 10B. Each recessed region 611 of the first wiring portion 61 and the second obverse electrode 12 of a relevant second semiconductor element 10B are bonded to each other via a conductive bonding material 69. The constituent material of the conductive bonding material 69 is not particularly limited, and may be solder, metal paste or sintered metal, for example. In the present embodiment, each recessed region 611 is formed with an opening 611a. Preferably, each opening 611a is formed to overlap with the middle part of a relevant first semiconductor element 10B in plan view. The openings 611a may be through-holes formed in the recessed regions 611 of the first wiring portion 61. The openings 611a may be used to position the second conductive member 6 relative to the conductive substrate 2. The shape in plan view of the openings 611a may be a perfect circle, or may be other shapes such as an ellipse or a rectangle.

As shown in FIGS. 5, 7 and 8, the second wiring portion 62 is located in the x2 direction from the first wiring portion 61. The second wiring portion 62 overlaps with the first semiconductor elements 10A and the first bond portions 52 in plan view. The second wiring portion 62 includes a first strip 621 and a second strip 622.

The first strip 621, which is spaced apart from the first wiring portion 61 in the x direction, is a strip-shaped part of the second wiring portion 62 that extends in the y direction in plan view. The first strip 621 overlaps with the first semiconductor elements 10A and the first bond portions 52 in plan view. The first strip 621 has a plurality of protruding regions 621a. As shown in FIG. 20, each protruding region 621a protrudes in the z2 direction relative to the rest of the first strip 621. As shown in FIGS. 7 and 20, the protruding regions 621a and the first semiconductor elements 10A overlap with each other in plan view. In the present embodiment, as will be understood from FIGS. 7 and 8, the recessed regions 611 of the first wiring portion 61 and the protruding regions 621a are at the same positions in the y direction.

The second strip 622 is connected to both the first strip 621 and the first wiring portion 61. The second strip 622 is a strip-shaped part extending in the x direction in plan view. In the present embodiment, the second wiring portion 62 has a plurality of (three) second strips 622. The second strips 622 are arranged at intervals in the y direction. The second strips 622 are arranged in parallel (or generally in parallel) to each other. The end in the x2 direction of each second strip 622 is connected between two protruding regions 621a adjacent to each other in the y direction of the first strip 621. Thus, the end in the x2 direction of each second strip 622 is connected to the first strip 621 at a location between adjacent first semiconductor elements 10A. The end in the x1 direction of each second strip 622 is connected between two recessed regions 611 adjacent to each other in the y direction of the first strip 621. Thus, the end in the x1 direction of each second strip 622 is connected to the first wiring portion 61 at a location between adjacent second semiconductor elements 10B. As shown in FIG. 18, in the present embodiment, each second strip 622 overlaps with the first part 51 (the flat section 511) of the first conductive member 5 in plan view. However, the second strips 622 (the second conductive member 6) overlap with none of the first openings 514 of the first part 51. Note that the boundary between each second strip 622 and the first strip 621 and the boundary between each second strip 622 and the first wiring portion 61 are indicated by imaginary lines in FIG. 8.

The third wiring portion 63 has a first end 631, a second end 632 and a plurality of openings 633. The first end 631 is connected to the first terminal 41. The first end 631 and the first terminal 41 are bonded to each other with a conductive bonding material 69. The third wiring portion 63 is a strip-shaped portion extending in the x direction as a whole in plan view. The third wiring portion 63 overlaps with both the first conductive portion 2A and the second conductive portion 2B in plan view. The second end 632 is spaced apart from the first end 631 in the x direction. As shown in FIGS. 7 and 8, the second end 632 is located in the x1 direction from the first end 631.

The third wiring portion 63 is connected to both the end in the y2 direction of the first wiring portion 61 and the end in the y2 direction of the first strip 621. Specifically, the second end 632 is connected to the end in the y2 direction of the first wiring portion 61. The portion between the first end 631 and the second end 632 is connected to the end in the y2 direction of the first strip 621.

Each of the openings 633 is a portion partially cut away in plan view. The openings 633 are spaced apart from each other in the x direction. In the illustrated example, the third wiring portion 63 has three openings 633. The opening 633 on the x2 side and the opening 633 in the middle in the x direction are located at positions that overlap with the obverse surface 201 of the first conductive portion 2A (the conductive substrate 2) in plan view and do not overlap with the first semiconductor elements 10A in plan view. The opening 633 on the x1 side is located at a position that overlaps with the obverse surface 201 of the second conductive portion 2B (the conductive substrate 2) in plan view and does not overlap with the second semiconductor elements 10B in plan view. In plan view, each opening 633 is at a location on the first conductive portion 2A (the second conductive portion 2B) that is offset in the y2 direction. In the present embodiment, each opening 633 is an arcuate notch recessed in the y2 direction from the edge on the y1 side of the third wiring portion 63. The shape in plan view of the openings 633 is not limited, and may be a notch as in the present embodiment, or a hole unlike the present embodiment.

The fourth wiring portion 64 has a third end 641, a fourth end 642, and a plurality of openings 643. The third end 641 is connected to the second terminal 42. The third end 641 and the second terminal 42 are bonded to each other with a conductive bonding material 69. The fourth wiring portion 64 is a strip-shaped portion extending in the x direction as a whole in plan view. The fourth wiring portion 64 is spaced apart from the third wiring portion 63 in the y direction. The fourth wiring portion 64 is located in the y1 direction from the third wiring portion 63. The fourth wiring portion 64 overlaps with both the first conductive portion 2A and the second conductive portion 2B in plan view. The fourth end 642 is spaced apart from the third end 641 in the x direction. As shown in FIGS. 7 and 8, the fourth end 642 is located in the x1 direction from the third end 641.

The fourth wiring portion 64 is connected to both the end in the y1 direction of the first wiring portion 61 and the end in the y1 direction of the first strip 621. Specifically, the fourth end 642 is connected to the end in the y1 direction of the first wiring portion 61. The portion between the third end 641 and the fourth end 642 is connected to the end in the y1 direction of the first strip 621.

Each of the openings 643 is a portion partially cut away in plan view. The openings 643 are spaced apart from each other in the x direction. In the illustrated example, the fourth wiring portion 64 has three openings 643. The opening 643 on the x2 side and the opening 643 in the middle in the x direction are located at positions that overlap with the obverse surface 201 of the first conductive portion 2A (the conductive substrate 2) in plan view and do not overlap with the first semiconductor elements 10A in plan view. The opening 643 on the x1 side is located at a position that overlaps with the obverse surface 201 of the second conductive portion 2B (the conductive substrate 2) in plan view and does not overlap with the second semiconductor elements 10B in plan view. In plan view, each opening 643 is at a location on the first conductive portion 2A (the second conductive portion 2B) that is offset in the y1 direction. In the present embodiment, each opening 643 is an arcuate notch recessed in the y1 direction from the edge on the y2 side of the fourth wiring portion 64. The shape in plan view of the openings 643 is not limited, and may be a notch as in the present embodiment, or a hole unlike the present embodiment.

The sealing resin 8 covers the first semiconductor elements 10A, the second semiconductor elements 10B, the conductive substrate 2, the support substrate 3 (excluding the bottom surface 302), a part of each of the first terminal 41, the second terminal 42, the third terminals 43 and the fourth terminal 44, a part of each of the control terminals 45, the first conductive member 5, the second conductive member 6, and the wires 71 to 74. The sealing resin 8 is made of a black epoxy resin, for example. The sealing resin 8 is formed by molding, for example. The sealing resin 8 has a dimension of about 35 mm to 60 mm in the x direction, a dimension of about 35 mm to 50 mm in the y direction, and a dimension of about 4 mm to 15 mm in the z direction, for example. These dimensions are measured at the largest portions in respective directions. The sealing resin 8 has a resin obverse surface 81, a resin reverse surface 82, and a plurality of resin side surfaces 831 to 834.

As shown in FIGS. 11, 13 and 19, the resin obverse surface 81 and the resin reverse surface 82 are spaced apart from each other in the z direction. The resin obverse surface 81 faces in the z2 direction, and the resin reverse surface 82 faces in the z1 direction. The control terminals 45 (the first control terminals 46A to 46E and the second control terminals 47A to 47D) protrude from the resin obverse surface 81. As shown in FIG. 12, the resin reverse surface 82 has a frame shape surrounding the bottom surface 302 of the support substrate 3 (the lower surface of the second metal layer 33) in plan view. The bottom surface 302 of the support substrate 3 is exposed at the resin reverse surface 82 and may be flush with the resin reverse surface 82. Each of the resin side surfaces 831 to 834 is connected to both the resin obverse surface 81 and the resin reverse surface 82 and sandwiched between these surfaces in the z direction. As shown in FIG. 4, the resin side surface 831 and the resin side surface 832 are spaced apart from each other in the x direction. The resin side surface 831 faces in the x1 direction, and the resin side surface 832 faces in the x2 direction. The two third terminals 43 protrude from the resin side surface 831, and the first terminal 41, the second terminal 42 and the fourth terminal 44 protrude from the resin side surface 832. As shown in FIG. 4, the resin side surface 833 and the resin side surface 834 are spaced apart from each other in the y direction. The resin side surface 833 faces in the y1 direction, and the resin side surface 834 faces in the y2 direction.

As shown in FIG. 4, the resin side surface 832 is formed with a plurality of recesses 832a. Each recess 832a is a portion recessed in the x direction in plan view. The recesses 832a include one formed between the first terminal 41 and the fourth terminal 44 in plan view, and one formed between the second terminal 42 and the fourth terminal 44 in plan view. The recesses 832a are provided to increase the creepage distance along the resin side surface 832 between the first terminal 41 and the fourth terminal 44 and the creepage distance along the resin side surface 832 between the second terminal 42 and the fourth terminal 44.

As shown in FIGS. 13 and 14, the sealing resin 8 has a plurality of first protrusions 851, a plurality of second protrusions 852, and resin cavities 86.

The first protrusions 851 protrude from the resin obverse surface 81 in the z direction. The first protrusions 851 are disposed at or near the four corners of the sealing resin 8 in plan view. Each of the first protrusions 851 has a first-protrusion end surface 851a at its extremity (the end on the z2 side). The first-protrusion end surfaces 851a of the first protrusions 851 are parallel (or generally parallel) with and located in the same plane (x-y plane) as the resin obverse surface 81. Each first protrusion 851 may have the shape of a hollow conical frustum with a bottom, for example. The first protrusions 851 are used as spacers when the semiconductor device A1 is mounted on a control circuit board or the like of a device configured to use the power produced by the semiconductor device A1. Each first protrusion 851 has a recess 851b and an inner wall surface 851c formed around the recess 851b. The shape of each first protrusion 851 may be columnar, and preferably cylindrical. Preferably, the recess 851b has a cylindrical shape, and the inner wall surface 851c is a single perfect circle in plan view.

The semiconductor device A1 may be mechanically fixed to a control circuit board or the like by screwing, for example. In such a case, female threads can be formed on the inner wall surfaces 851c of the recesses 851b of the first protrusions 851. Insert nuts may be embedded in the recesses 851b of the first protrusions 851.

As shown in FIG. 14, the second protrusions 852 protrude from the resin obverse surface 81 in the z direction. The second protrusions 852 overlap with the control terminals 45 in plan view. The metal pins 452 of the control terminals 45 protrude from the second protrusions 852, respectively. Each of the second protrusions 852 may have the shape of a conical frustum, for example. Each second protrusion 852 covers the holder 451 and a part of the metal pin 452 of a control terminal 45.

As shown in FIG. 13, the resin cavities 86 extend from the resin obverse surface 81 to the obverse surface 201 of the conductive substrate 2. Each resin cavity 86 is tapered, with its sectional area decreasing as proceeding in the z direction from the resin obverse surface 81 toward the obverse surface 201. The resin cavities 86 are formed during the molding of the sealing resin 8 and the area where the sealing resin 8 is not formed during the molding process.

Though illustration is omitted, the resin cavities 86 are formed, for example, because the flowable resin material could not flow into these areas as a result of these areas being occupied by pressing members during the molding process of the sealing resin 8. Such pressing members are used to apply pressing force to the obverse surface 201 of the conductive substrate 2 during the molding process and inserted into the openings 633 and openings 643 of the second conductive member 6. In this way, the pressing members hold the conductive substrate 2 without interfering with the second conductive member 6, and warpage of the support substrate 3, to which the conductive substrate 2 is bonded, is suppressed.

In the present embodiment, the semiconductor device A1 includes resin fill portions 88 as shown in FIG. 13. The resin fill portions 88 are loaded into the resin cavities 86 to fill the resin cavities 86. The resin fill portions 88 may be made of epoxy resin as with the sealing resin 8, but may be made of a material different from the sealing resin 8.

The effect and advantages of the present embodiment are described below.

The semiconductor device A1 includes the plurality of first semiconductor elements 10A, the conductive substrate 2, the first conductive member 5, and the sealing resin 8. Each of the first semiconductor elements 10A has a switching function and is bonded to the first conductive portion 2A (the conductive substrate 2). The first conductive member 5 constitutes a path for the main circuit current switched by the first semiconductor elements 10A. The first conductive member 5 includes the first part 51. The first part 51 overlaps with both the first conductive portion 2A and the second conductive portion 2B in plan view and is spaced apart from the obverse surface 201 toward the z2 side in the z direction. The first part 51 (the flat section 511) has first openings 514.

With such a configuration, the first conductive member 5 (the first part 51) can have a relatively large area in plan view. In the semiconductor device A1, therefore, the main circuit current flowing from the first semiconductor elements 10A in the first conductive member 5 flows through a current path having a large area. Thus, the semiconductor device A1 has a configuration favorable for carrying a large current.

The first part 51 has the first openings 514. With such a configuration, when the flowable resin material is injected to form the sealing resin 8, the resin material can easily flow between the lower side (the z1 side) and the upper side (the z2 side) in the first part 51 (the first conductive member 5) through the first openings 514. Further, when bubbles exist on the lower side (the z1 side) of the first part 51 in injecting the flowable resin material, such bubbles will move to the upper side (the z2 side) of the first part 51 through the first openings 514. Thus, it is possible to suppress incomplete filling of the sealing resin 8 on the lower side (the z1 side) of the first part 51 and prevent generation of voids. The semiconductor device A1 with such a configuration has improved reliability in carrying a large current.

The first openings 514 provided in the first part 51 overlap with the gap 205 between the first conductive portion 2A and the second conductive portion 2B in plan view. Such a configuration suppresses incomplete filling of the sealing resin 8 in the gap 205 between the first conductive portion 2A and the second conductive portion 2B. In the conductive substrate 2, a large potential difference can be produced between the first conductive portion 2A and the second conductive portion 2B, which are separated from each other. According to the semiconductor device A1 of the present embodiment, the reliability in carrying a large current is further improved.

The first openings 514 overlap with the first conductive portion 2A (the conductive substrate 2) in plan view. With such a configuration, incomplete filling of the sealing resin 8 can be suppressed in a relatively narrow gap between the first part 51 and the first conductive portion 2A (the conductive substrate 2) in the z direction.

The first part 51 includes the flat section 511, the first bent sections 512, and the second bent sections 513. In the present embodiment, the first semiconductor elements 10A are arranged at intervals in the y direction. The flat section 511 extends continuously in the y direction to correspond to the areas in which the first semiconductor elements 10A are arranged. The flat section 511 is formed with the plurality of first openings 514. Each of the first openings 514 is provided to correspond to a respective one of the first semiconductor elements 10A. The semiconductor device A1 including such a flat section 511 is favorable for carrying a large current. Further, because the flat section 511 has plurality of first openings 514, incomplete filling of the sealing resin 8 on the lower side (the z1 side) of the first part is more reliably suppressed.

The semiconductor device A1 includes the plurality of second semiconductor elements 10B and the second conductive member 6. Each of the second semiconductor elements 10B has a switching function and is bonded to the second conductive portion 2B (the conductive substrate 2). The second conductive member 6 constitutes a path for the main circuit current switched by the second semiconductor elements 10B. The semiconductor device A1 with such a configuration is more favorable for carrying a large current.

The second conductive member 6 includes the first wiring portion 61, the second wiring portion 62 (the first strip 621 and the second strip 622), the third wiring portion 63, and the fourth wiring portion 64 and provides a grid-like current path extending vertically and horizontally in plan view. Thus, the second conductive member 6 can have a relatively large area in plan view while being limited by other components of the semiconductor device A1. In the semiconductor device A1, the main circuit current flowing in the second conductive member 6 through the first wiring portion 61 flows through a distributed current path having a large area. Thus, the semiconductor device A1 have a configuration favorable for carrying a large current.

In the present embodiment, the second strips 622 of the second conductive member 6 overlap with the first part 51 (the flat section 511) of the first conductive member 5 in plan view. The semiconductor device A1 with such a configuration is suitable for reducing the inductance component and more favorable for carrying a large current. The second strips 622 (the second conductive member 6) overlap with none of the first openings 514 of the first part 51. Therefore, the second conductive member 6 does not reduce the effect of the first openings 514 (suppression of incomplete filling of the sealing resin 8 and prevention of void generation).

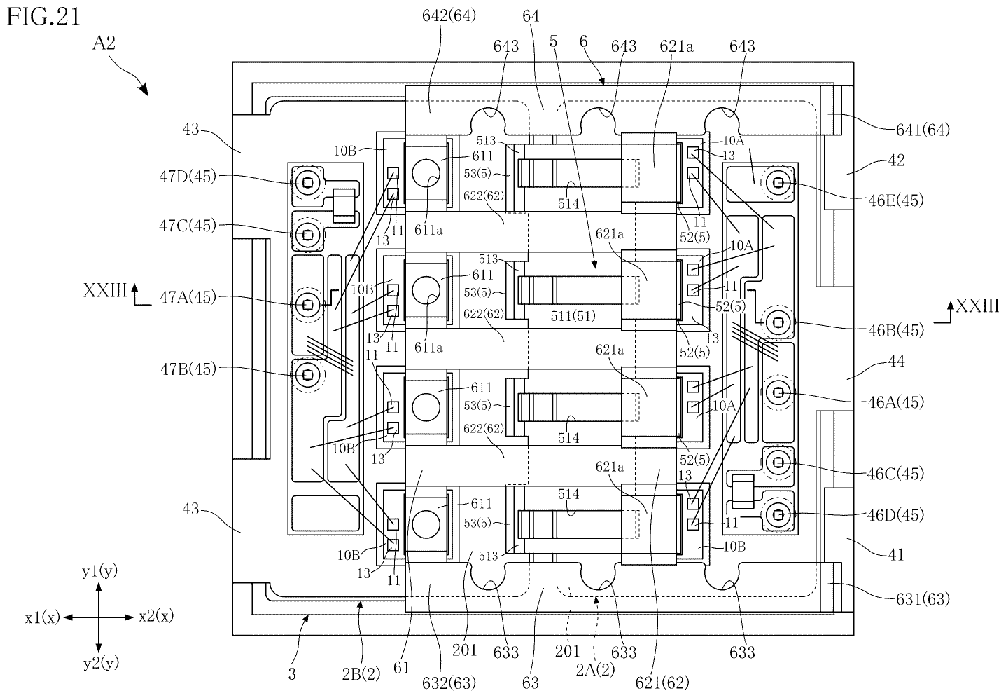

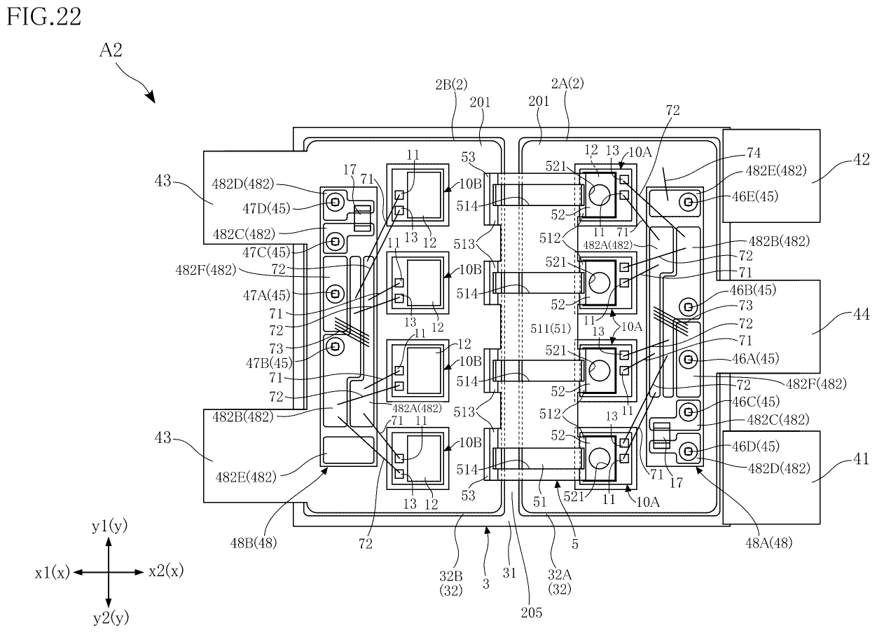

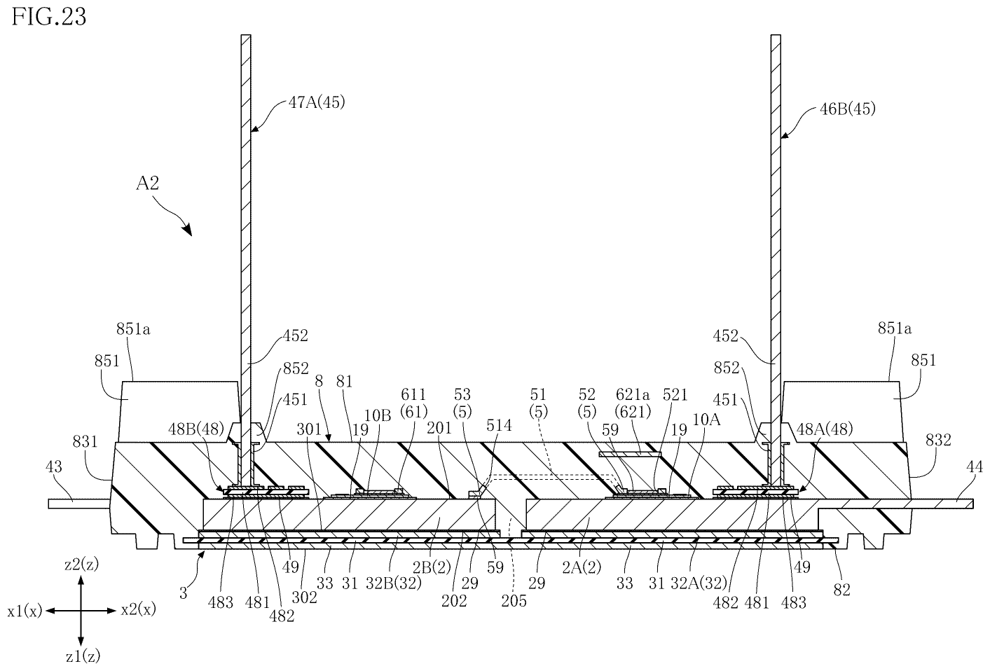

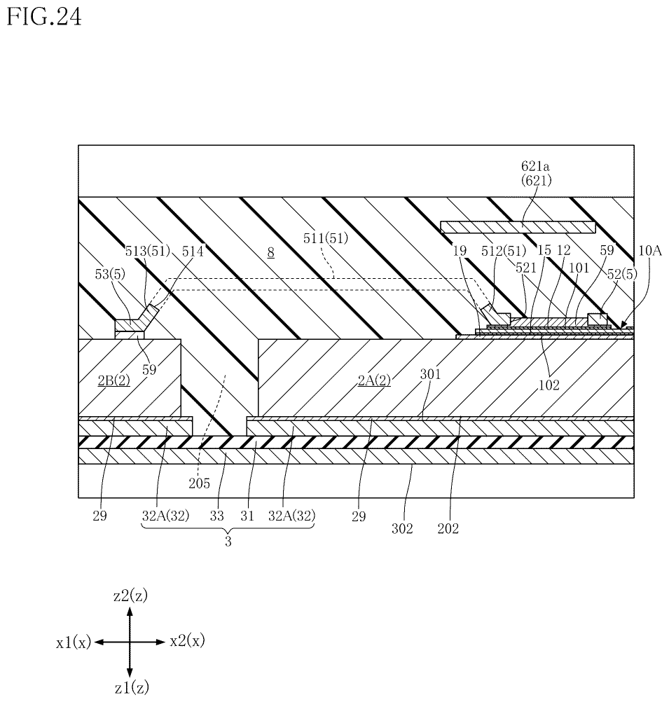

FIGS. 21 to 24 show a semiconductor device according to a variation of the first embodiment. FIG. 21 is a plan view corresponding to FIG. 7 of the above-described embodiment. FIG. 22 is a plan view from which the sealing resin and the second conductive member are omitted. FIG. 23 is a sectional view taken along line XXIII-XXIII in FIG. 21. FIG. 24 is a partially enlarged view in which a portion of FIG. 23 is enlarged. In FIG. 21 and the subsequent drawings, the elements that are identical or similar to those of the semiconductor device A1 of the above-described embodiment are denoted by the same reference signs as those of the above-described embodiment, and the description thereof is omitted as appropriate.

The semiconductor device A2 of the present variation differs from the above-described embodiment in configuration of the first conductive member 5, and in particular, in configuration of the first openings 514 formed in the first part 51. In the present variation, each of the first openings 514 is rectangular in plan view. Each first opening 514 is formed to bridge over the flat section 511, a first bent section 512, and a second bent section 513. Each first opening 514 is a through-hole penetrating in the plate thickness direction of the first part 51. In the present embodiment, each first opening 514 overlaps with a gap 205 between the first conductive portion 2A and the second conductive portion 2B in plan view. Also, in the present variation, each first opening 514 overlaps with both the first conductive portion 2A and the second conductive portion 2B.

In the semiconductor device A2, the first conductive member 5 (the first part 51) can have a relatively large area in plan view. In the semiconductor device A2, therefore, the main circuit current flowing from the first semiconductor elements 10A in the first conductive member 5 flows through a current path having a large area. Thus, the semiconductor device A2 has a configuration favorable for carrying a large current.

The first part 51 has the first openings 514. With such a configuration, when the flowable resin material is injected to form the sealing resin 8, the resin material can easily flow between the lower side (the z1 side) and the upper side (the z2 side) in the first part 51 (the first conductive member 5) through the first openings 514. Further, when bubbles exist on the lower side (the z1 side) of the first part 51 in injecting the flowable resin material, such bubbles will move to the upper side (the z2 side) of the first part 51 through the first openings 514. Thus, it is possible to suppress incomplete filling of the sealing resin 8 on the lower side (the z1 side) of the first part 51 and prevent generation of voids. The semiconductor device A2 with such a configuration has improved reliability in carrying a large current.

In the semiconductor device A2, each of the first openings 514 is formed to bridge over the flat section 511, a first bent section 512 and a second bent section 513. In the present embodiment, each first opening 514 overlaps with a gap 205 between the first conductive portion 2A and the second conductive portion 2B and also overlaps with both the first conductive portion 2A and the second conductive portion 2B in plan view. Such a configuration further facilitates the flow of the resin material and the movement of bubbles through the first openings 514 during the injection of a flowable resin material to form the sealing resin 8. Thus, it is possible to more reliably suppress incomplete filling of the sealing resin 8 on the lower side (the z1 side) of the first part 51 and prevent generation of voids.

In the present variation, the second bent sections 513 are located close to the first semiconductor elements 10A, and the first openings 514 are formed in the second bent sections 513. Thus, incomplete filling of the sealing resin 8 and void generation can be effectively prevented near the first semiconductor elements 10A. Thus, space discharge caused by voids can be prevented at or around the first semiconductor elements 10A. According to the semiconductor device A2, therefore, the reliability in carrying a large current is further improved. The same effect as the semiconductor device A1 of the above-described embodiment is also provided owing to the configuration in common with the above-described embodiment.

The semiconductor device according to present disclosure is not limited to the above-described embodiments. Various modifications in design may be made freely in the specific structure of each part of the semiconductor device according to the present disclosure.

Although one common first conductive member 5 is used for a plurality of first semiconductor elements 10A in the above-described embodiment, the present disclosure is not limited to this. For example, a plurality of first conductive members 5 may be provided to correspond to the plurality of first semiconductor elements 10A.

The present disclosure includes embodiments described in the following clauses.

Clause 1.

A semiconductor device comprising:

a conductive substrate including an obverse surface facing a first side in a thickness direction and a reverse surface facing away from the obverse surface;

at least one first semiconductor element bonded to the obverse surface and having a switching function;

a first conductive member constituting a path for a main circuit current switched by the first semiconductor element; and

a sealing resin covering the first semiconductor element, the first conductive member, and at least a part of the conductive substrate, wherein

the conductive substrate includes a first conductive portion and a second conductive portion disposed in a mutually spaced manner on a first side and on a second side, respectively, in a first direction orthogonal to the thickness direction,

the first semiconductor element is electrically bonded to the first conductive portion,

the first conductive member includes a first part overlapping with both the first conductive portion and the second conductive portion as viewed in the thickness direction and spaced apart from the obverse surface toward the first side in the thickness direction, and

the first part includes a first opening.

Clause 2.

The semiconductor device according to clause 1, wherein the first conductive member comprises a plate made of a metal.

Clause 3.

The semiconductor device according to clause 2, wherein the first opening overlaps with a gap between the first conductive portion and the second conductive portion as viewed in the thickness direction.

Clause 4.

The semiconductor device according to clause 3, wherein the first opening overlaps with at least one of the first conductive portion and the second conductive portion as viewed in the thickness direction.

Clause 5.

The semiconductor device according to any one of clauses 2 to 4, wherein the first conductive member includes: a first bond portion located on the first side in the first direction with respect to the first part and bonded to the first semiconductor element; and a second bond portion located on the second side in the first direction with respect to the first part and bonded to the second conductive portion.

Clause 6.

The semiconductor device according to clause 5, wherein the first part includes a flat section, a first bent section, and a second bent section, the flat section being disposed in parallel to the obverse surface and overlapping with the first conductive portion and the second conductive portion as viewed in the thickness direction, the first bent section being connected to both an end on the first side in the first direction of the flat section and the first bond portion and extending toward the second side in the thickness direction as proceeding toward the first side in the first direction, the second bent section being connected to both an end on the second side in the first direction of the flat section and the second bond portion and extending toward the second side in the thickness direction as proceeding toward the second side in the first direction, and

the first opening is formed at least in the flat section.

Clause 7.

The semiconductor device according to clause 6, wherein the first opening is formed in at least one of the first bent section and the second bent section.

Clause 8.

The semiconductor device according to clause 6 or 7, wherein the at least one first semiconductor element includes a plurality of first semiconductor elements, the plurality of first semiconductor elements being arranged at intervals in a second direction orthogonal to both the thickness direction and the first direction.

Clause 9.

The semiconductor device according to clause 8, wherein the first opening includes a plurality of openings arranged in the second direction to correspond to the plurality of first semiconductor elements, respectively.

Clause 10.

The semiconductor device according to clause 9, wherein the flat section extends continuously to correspond to an area in which the first semiconductor elements are arranged in the second direction.

Clause 11.

The semiconductor device according to clause 9 or 10, wherein the first bond portion, the second bond portion, the first bent section and the second bent section are disposed to correspond to each of the plurality of first semiconductor elements in the second direction.

Clause 12.

The semiconductor device according to any one of clauses 9 to 11, further comprising:

a plurality of second semiconductor elements electrically bonded to the second conductive portion and having a switching function; and

a second conductive member comprising a plate made of a metal, wherein

the second conductive member includes a first wiring portion and a second wiring portion,

the first wiring portion is connected to the plurality of second semiconductor elements, and

the second wiring portion is located on the first side in the first direction with respect to the first wiring portion and overlaps with both the plurality of first semiconductor elements and the first bond portion.

Clause 13.

The semiconductor device according to clause 12, wherein the plurality of second semiconductor elements are arranged at intervals in the second direction, and

the plurality of first semiconductor elements and the plurality of second semiconductor elements overlap with each other as viewed in the first direction.

Clause 14.

The semiconductor device according to clause 13, wherein the second wiring portion includes a first strip and a second strip,

the first strip is spaced apart from the first wiring portion in the first direction and overlaps with both the plurality of first semiconductor elements and the first bond portion as viewed in the thickness direction, and

the second strip is connected, at an end thereof on the first side in the first direction, to the first strip at a location between adjacent ones of the first semiconductor elements and connected, at an end thereof on the second side in the first direction, to the first wiring portion at a location between adjacent ones of the second semiconductor elements.

Clause 15.

The semiconductor device according to clause 14, wherein the second strip overlaps with the flat section of the first conductive member as viewed in the thickness direction.

Clause 16.

The semiconductor device according to clause 14 or 15, wherein the second conductive member includes a third wiring portion and a fourth wiring portion,

the third wiring portion is connected to both one end on a first side in the second direction of the first wiring portion and one end on the first side in the second direction of the first strip and extends in the first direction, and

the fourth wiring portion is connected to both one end on a second side in the second direction of the first wiring portion and one end on the second side in the second direction of the first strip and extends in the first direction.

Clause 17.

The semiconductor device according to any one of clauses 12 to 15, wherein the second conductive member overlaps with none of the plurality of openings of the first opening as viewed in the thickness direction.

Clause 18.

The semiconductor device according to any one of clauses 12 to 17, wherein the first conductive member and the second conductive member contain copper.

Clause 19.

The semiconductor device according to any one of clauses 2 to 18, wherein the first opening is a through-hole penetrating in a plate thickness direction of the first part.

### REFERENCE NUMERALS

A1, A2: Semiconductor device
10A: First semiconductor element
10B: Second semiconductor element
101: Element obverse surface
102: Element reverse surface 11: First obverse electrode
12: Second obverse electrode
13: Third obverse electrode 15: Reverse electrode
17: Thermistor
19: Conductive bonding material 2: Conductive substrate
2A: First conductive portion
2B: Second conductive portion 201: Obverse surface
202: Reverse surface 205: Gap
29: Conductive bonding material 3: Support substrate
301: Support surface 302: Bottom surface
31: Insulating layer 32: First metal layer
32A: First portion 32B: Second portion
321: First bond layer 33: Second metal layer
41: First terminal 42: Second terminal
43: Third terminal 44: Fourth terminal
45: Control terminal 451: Holder
452: Metal pin 459: Conductive bonding material
46A, 46B, 46C, 46D, 46E: First control terminal
47A, 47B, 47C, 47D: Second control terminal
48: Control terminal support 481: Insulating layer
482: First metal layer 482A: First portion
482B: Second portion 482C: Third portion
482D: Fourth portion 482E: Fifth portion
482F: Sixth portion 483: Second metal layer
49: Bonding material 5: First conductive member
51: First part 511: Flat section 512: First bent section
513: Second bent section 514: First opening
52: First bond portion 521: Opening
53: Second bond portion 59: Conductive bonding material
6: Second conductive member 61: First wiring portion
611: Recessed region 611a: Opening
62: Second wiring portion 621: First strip
621a: Protruding region 622: Second strip
63: Third wiring portion 631: First end
632: Second end 633: Opening
64: Fourth wiring portion 641: Third end 642: Fourth end
643: Opening 69: Conductive bonding material
71, 72, 73, 74: Wire 8: Sealing resin
81: Resin obverse surface 82: Resin reverse surface
831, 832: Resin side surface
832a: Recess 833, 834: Resin side surface
851: First protrusion 851a: First-protrusion end surface
851b: Recess 851c: Inner wall surface
852: Second protrusion 86: Resin cavity
88: Resin fill portion

1. A semiconductor device comprising:
a conductive substrate including an obverse surface facing a first side in a thickness direction and a reverse surface facing away from the obverse surface;
at least one first semiconductor element bonded to the obverse surface and having a switching function;
a first conductive member constituting a path for a main circuit current switched by the first semiconductor element; and
a sealing resin covering the first semiconductor element, the first conductive member, and at least a part of the conductive substrate, wherein
the conductive substrate includes a first conductive portion and a second conductive portion disposed in a mutually spaced manner on a first side and on a second side, respectively, in a first direction orthogonal to the thickness direction,
the first semiconductor element is electrically bonded to the first conductive portion,
the first conductive member includes a first part overlapping with both the first conductive portion and the second conductive portion as viewed in the thickness direction and spaced apart from the obverse surface toward the first side in the thickness direction, and
the first part includes a first opening.

2. The semiconductor device according to claim 1, wherein the first conductive member comprises a plate made of a metal.

3. The semiconductor device according to claim 2, wherein the first opening overlaps with a gap between the first conductive portion and the second conductive portion as viewed in the thickness direction.

4. The semiconductor device according to claim 3, wherein the first opening overlaps with at least one of the first conductive portion and the second conductive portion as viewed in the thickness direction.

5. The semiconductor device according to claim 2, wherein the first conductive member includes: a first bond portion located on the first side in the first direction with respect to the first part and bonded to the first semiconductor element; and a second bond portion located on the second side in the first direction with respect to the first part and bonded to the second conductive portion.

6. The semiconductor device according to claim 5, wherein the first part includes a flat section, a first bent section, and a second bent section, the flat section being disposed in parallel to the obverse surface and overlapping with the first conductive portion and the second conductive portion as viewed in the thickness direction, the first bent section being connected to both an end on the first side in the first direction of the flat section and the first bond portion and extending toward the second side in the thickness direction as proceeding toward the first side in the first direction, the second bent section being connected to both an end on the second side in the first direction of the flat section and the second bond portion and extending toward the second side in the thickness direction as proceeding toward the second side in the first direction, and
the first opening is formed at least in the flat section.

7. The semiconductor device according to claim 6, wherein the first opening is formed in at least one of the first bent section and the second bent section.

8. The semiconductor device according to claim 6, wherein the at least one first semiconductor element includes a plurality of first semiconductor elements, the plurality of first semiconductor elements being arranged at intervals in a second direction orthogonal to both the thickness direction and the first direction.

9. The semiconductor device according to claim 8, wherein the first opening includes a plurality of openings arranged in the second direction to correspond to the plurality of first semiconductor elements, respectively.

10. The semiconductor device according to claim 9, wherein the flat section extends continuously to correspond to an area in which the first semiconductor elements are arranged in the second direction.

11. The semiconductor device according to claim 9, wherein the first bond portion, the second bond portion, the first bent section and the second bent section are disposed to correspond to each of the plurality of first semiconductor elements in the second direction.

12. The semiconductor device according to claim 9, further comprising:
a plurality of second semiconductor elements electrically bonded to the second conductive portion and having a switching function; and
a second conductive member comprising a plate made of a metal, wherein
the second conductive member includes a first wiring portion and a second wiring portion,
the first wiring portion is connected to the plurality of second semiconductor elements, and
the second wiring portion is located on the first side in the first direction with respect to the first wiring portion and overlaps with both the plurality of first semiconductor elements and the first bond portion.

13. The semiconductor device according to claim 12, wherein the plurality of second semiconductor elements are arranged at intervals in the second direction, and
the plurality of first semiconductor elements and the plurality of second semiconductor elements overlap with each other as viewed in the first direction.

14. The semiconductor device according to claim 13, wherein the second wiring portion includes a first strip and a second strip,
the first strip is spaced apart from the first wiring portion in the first direction and overlaps with both the plurality of first semiconductor elements and the first bond portion as viewed in the thickness direction, and
the second strip is connected, at an end thereof on the first side in the first direction, to the first strip at a location between adjacent ones of the first semiconductor elements and connected, at an end thereof on the second side in the first direction, to the first wiring portion at a location between adjacent ones of the second semiconductor elements.

15. The semiconductor device according to claim 14, wherein the second strip overlaps with the flat section of the first conductive member as viewed in the thickness direction.

16. The semiconductor device according to claim 14, wherein the second conductive member includes a third wiring portion and a fourth wiring portion,
the third wiring portion is connected to both one end on a first side in the second direction of the first wiring portion and one end on the first side in the second direction of the first strip and extends in the first direction, and
the fourth wiring portion is connected to both one end on a second side in the second direction of the first wiring portion and one end on the second side in the second direction of the first strip and extends in the first direction.

17. The semiconductor device according to claim 12, wherein the second conductive member overlaps with none of the plurality of openings of the first opening as viewed in the thickness direction.

18. The semiconductor device according to claim 12, wherein the first conductive member and the second conductive member contain copper.

19. The semiconductor device according to claim 2, wherein the first opening is a through-hole penetrating in a plate thickness direction of the first part.
